(19) United States
(12) Patent Application Publication
(10) Pub. No.: US 2026/0096202 A1
(43) Pub. Date: Apr. 2, 2026

(54) INTEGRATED CIRCUIT DEVICE AND METHOD OF MANUFACTURING

(71) Applicant: TAIWAN SEMICONDUCTOR MANUFACTURING COMPANY, LTD., Hsinchu (TW)

(72) Inventors: Wei-Xiang YOU, Hsinchu (TW); Tsung-Kai CHIU, Hsinchu (TW); Ting-Yun WU, Hsinchu (TW); Chun-Yen LIN, Hsinchu (TW); Szuya LIAO, Hsinchu (TW)

(21) Appl. No.: 19/018,342

(22) Filed: Jan. 13, 2025

Related U.S. Application Data
(60) Provisional application No. 63/701,194, filed on Sep. 30, 2024.

(51) Int. Cl. H10D 84/85; H10D 84/01

(52) U.S. Cl. CPC H10D 84/856; H10D 84/0186; H10D 84/851

(57) ABSTRACT

Various CFET in-cell MOL connections for power delivery under buried power rail scheme are provided. An integrated circuit (IC) device includes a device stack, a top contact structure, a back side power rail, and a via interconnect. The device stack includes a bottom semiconductor device, and a top semiconductor device stacked over the bottom semiconductor device along a direction. The top contact structure is over and in electrical contact with a source/drain of the top semiconductor device. The via interconnect extends between and electrically couples the top contact structure and the back side power rail. The via interconnect tapers along the direction from the back side power rail towards the top contact structure.

### RELATED APPLICATION(S)

This application claims the benefit of U.S. Provisional Application No. 63/701,194, filed Sep. 30, 2024, which is herein incorporated by reference in its entirety.

### BACKGROUND

An integrated circuit (“IC”) device includes one or more semiconductor devices represented in an IC layout diagram (also referred to as “layout diagram,” “layout” or “IC layout”). A layout diagram is hierarchical and includes modules which carry out higher-level functions in accordance with the semiconductor device's design specifications. The modules are often built from a combination of cells, each of which represents one or more semiconductor structures configured to perform a specific function. Cells having pre-designed layout diagrams, sometimes known as standard cells, are stored in standard cell libraries (hereinafter “libraries” or “cell libraries” for simplicity) and accessible by various tools, such as electronic design automation (EDA) tools, to generate, optimize and verify designs for ICs.

To reduce the sizes of IC devices, sometimes a layer of semiconductor devices is formed, or bonded, over another layer of semiconductor devices. Examples include complementary field effect transistor (CFET) devices in which an upper or top semiconductor device overlies a lower or bottom semiconductor device in a stack configuration.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic perspective view of a stack of semiconductor devices, in accordance with some embodiments.

FIG. 1B is a schematic perspective view, and FIGS. 1C, 1D, 1E and 1F are schematic cross-sectional views of an IC device at various stages in a manufacturing process, in accordance with some embodiments.

FIG. 2A is a block diagram of an IC device, in accordance with some embodiments.

FIG. 2B is a schematic view of a layout an IC device, in accordance with some embodiments.

FIG. 3A is a schematic cross-sectional view and FIG. 3B is a schematic view of a layout of one or more circuit regions of one or more IC devices, in accordance with some embodiments.

FIG. 4A is a schematic cross-sectional view and FIG. 4B is a schematic view of a layout of one or more circuit regions of one or more IC devices, in accordance with some embodiments.

FIG. 5A is a schematic cross-sectional view and FIG. 5B is a schematic view of a layout of one or more circuit regions of one or more IC devices, in accordance with some embodiments.

FIGS. 6A, 6B, 6C are schematic views of layouts of various circuit regions of one or more IC devices, in accordance with some embodiments.

FIGS. 7A, 7B are schematic perspective views of various circuit regions of one or more IC devices, in accordance with some embodiments.

FIGS. 8A, 8B, 8C, 8D, 8E are schematic cross-sectional views of an IC device at various stages in a manufacturing process, in accordance with some embodiments.

FIGS. 9A, 9B, 9C, 9D, 9E are schematic cross-sectional views of an IC device at various stages in a manufacturing process, in accordance with some embodiments.

FIGS. 10A, 10B are schematic cross-sectional views of an IC device at various stages in a manufacturing process, in accordance with some embodiments.

FIGS. 11A, 11B each include a schematic diagram of a portion of an IC manufacturing process, and schematic views of an IC device at various stages in the manufacturing process, in accordance with some embodiments.

FIGS. 12A-12D are flowcharts of various methods, in accordance with some embodiments.

FIG. 13 is a block diagram of an electronic design automation (EDA) system in accordance with some embodiments.

FIG. 14 is a block diagram of an IC device manufacturing system, and an IC manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, an IC device includes a power delivery structure configured to provide various power supply voltages, e.g., a positive power supply voltage VDD and a reference voltage such as the ground voltage VSS, to various circuits and/or circuit components of the IC device. In some configurations, the power delivery structure is arranged at both a front side and an opposite, back side of the IC device, and comprises one or more power tap structures configured to provide power from one of the front side and the back side to the other side. A chip area occupied by power tap structures or power tap cells is sometimes referred to as a power tap area.

In some embodiments, a via interconnect is included in a circuit of an IC device, and is configured to deliver power from one side of the IC device to the other side, e.g., from the back side to the front side. In at least one embodiment, the via interconnect is embedded in a gate length defining dielectric structures that limits or defines a length of one or more gates in the circuit. In some embodiments, the via interconnect is arranged on a boundary of a first cell corresponding to the circuit, and is configured to be shared with a further circuit corresponding to a second cell placed in abutment with the first cell. In at least one embodiment, the via interconnect is configured as a power via for power delivery for a single cell or a single CFET device. In some embodiments, the via interconnect is configured as a power wall for power delivery for multiple cells or multiple CFET devices. In one or more embodiments, as the via interconnect is configured to deliver power from one side of the IC device to the other side, it is possible to eliminate all power tap structures, or at least reduce the number of power tap structures, in the IC device. As a result, in one or more embodiments, the power tap area of the IC device is advantageously reduced, while ensuring that a voltage drop (or IR drop) in the power delivery structure is within a predetermined or acceptable range.

In some embodiments, compared to other approaches, the formation of a via interconnect does not increase the number of masks, e.g., extreme ultraviolet (EUV) masks, required for a middle-of-line (MOL) fabrication, or even reduces the number of EUV masks required for the MOL fabrication. In at least one embodiment, compared to other approaches, the formation of a via interconnect insignificantly increases number of EUV masks required for the MOL fabrication, e.g., by a single EUV mask. One or more further advantages are achievable in various embodiments, as described herein.

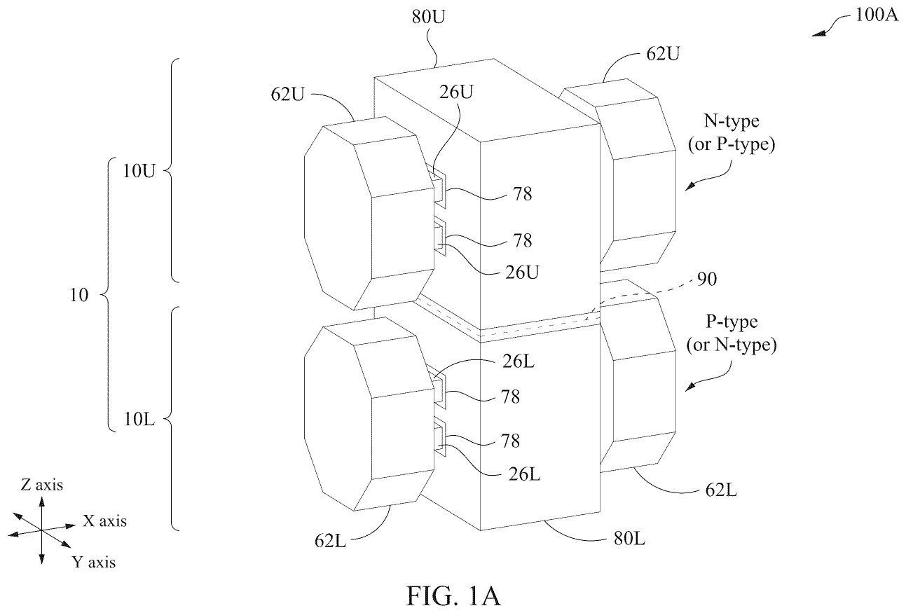

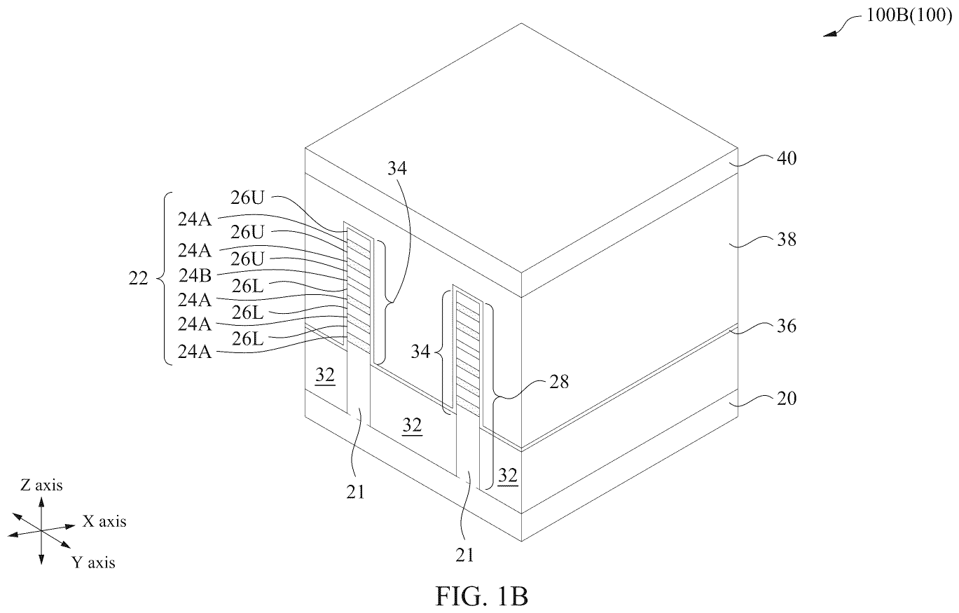

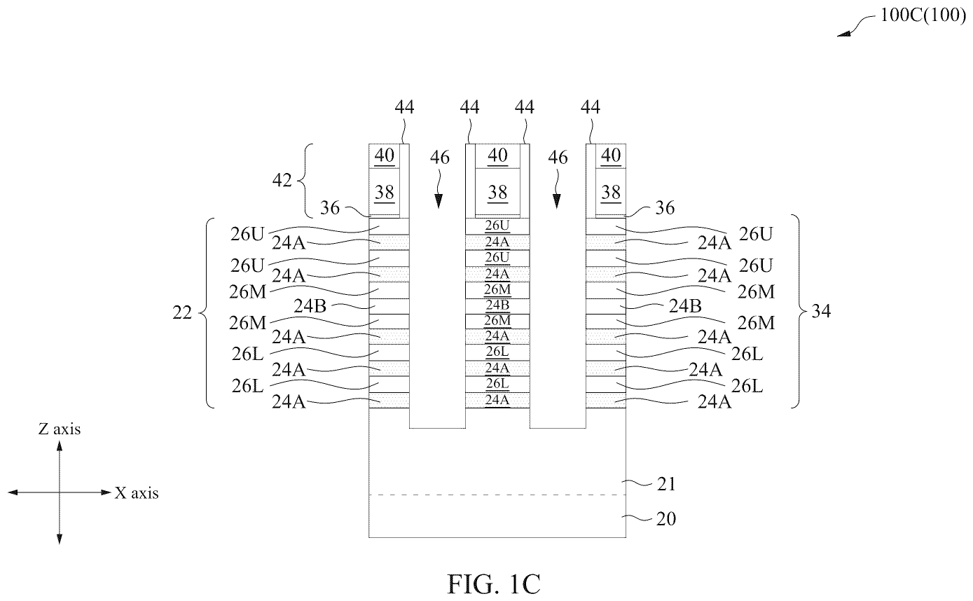

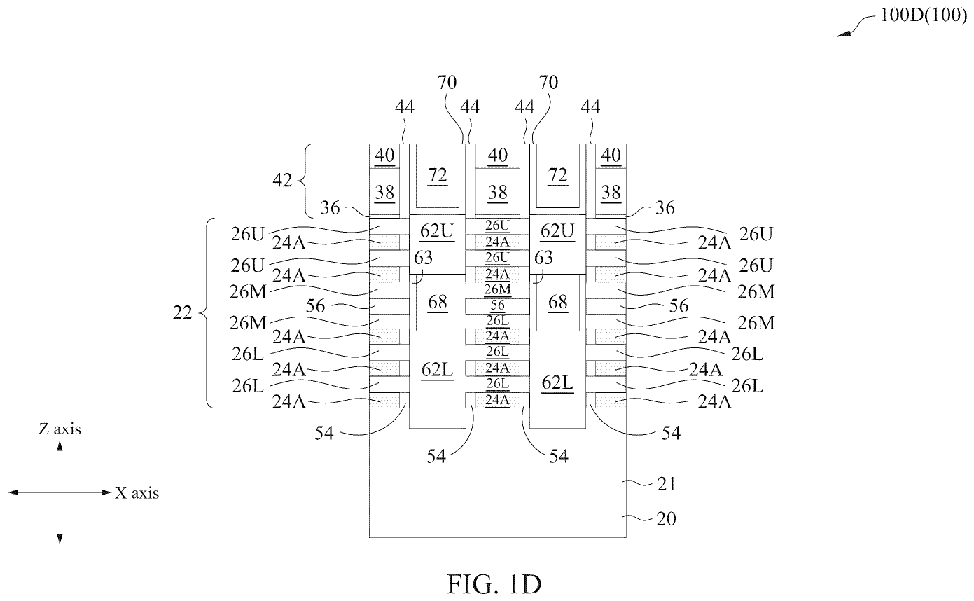

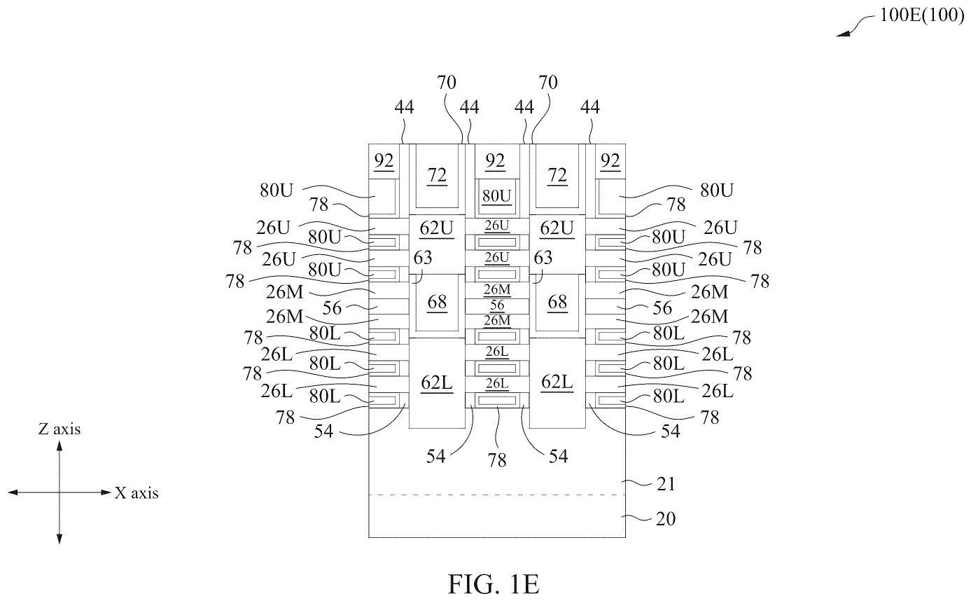

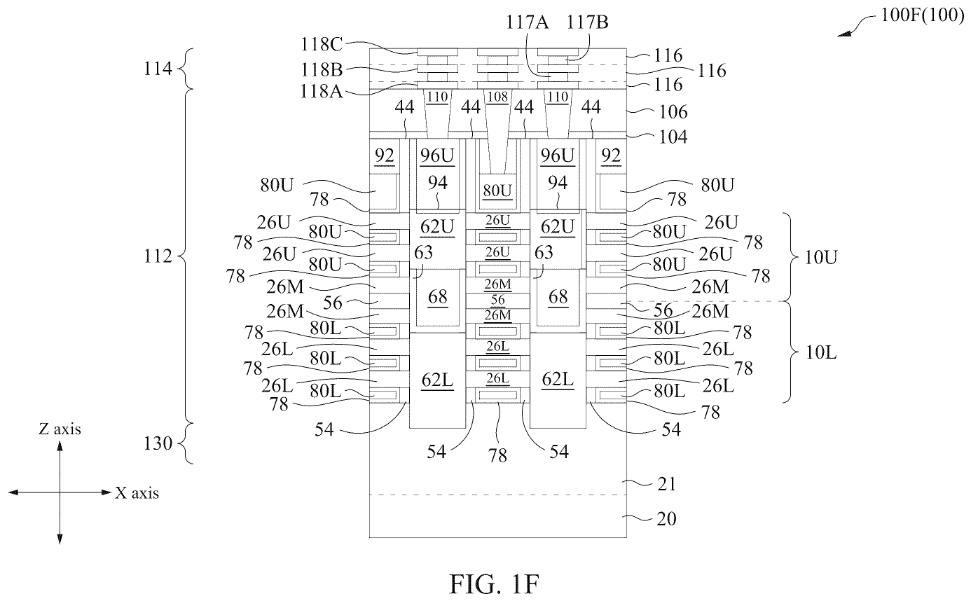

FIG. 1A is a schematic perspective view of a stack of semiconductor devices, or a device stack, 100A, in accordance with some embodiments.

The device stack 100A comprises a stacked structure 10 of a bottom semiconductor device 10L and a top semiconductor device 10U. The bottom semiconductor device 10L is over a substrate. For simplicity, the substrate is not illustrated in FIG. 1A. An example substrate is described with respect to FIGS. 1B-1F. The top semiconductor device 10U is physically stacked over the bottom semiconductor device 10L in a thickness direction of the substrate. The thickness direction is designated as a Z axis in FIG. 1A. In the example configuration in FIG. 1A, the top semiconductor device 10U and the bottom semiconductor device 10L are of different conductivity types. Other configurations where both top semiconductor device 10U and bottom semiconductor device 10L are of the same conductivity type are within the scopes of various embodiments. Conductivity type is sometimes referred to as semiconductor type. Examples of conductivity type include N-type and P-type. In an example, the top semiconductor device 10U is an N-type semiconductor device, the bottom semiconductor device 10L is a P-type semiconductor device, and the stacked structure 10 is referred to as an N-on-P structure. In another example, the top semiconductor device 10U is a P-type semiconductor device, the bottom semiconductor device 10L is an N-type semiconductor device, and the stacked structure 10 is referred to as a P-on-N structure. For simplicity, various example embodiments described herein include N-on-P structures. One or more features, functions and/or advantages of embodiments with N-on-P structures are applicable to and/or achievable in embodiments with P-on-N structures.

Examples of semiconductor devices include, but are not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like. In the example configuration in FIG. 1A, the top semiconductor device 10U and bottom semiconductor device 10L are nanosheet FETs. Other semiconductor device configurations are within the scopes of various embodiments. In some embodiments, the top semiconductor device 10U and bottom semiconductor device 10L have different semiconductor device configurations. For example, the bottom semiconductor device 10L is a planar MOS transistor whereas the top semiconductor device 10U is a nanosheet FET.

The top semiconductor device 10U comprises a gate 80U, and source/drains 62U on opposite sides of the gate 80U along an X axis. The gate 80U extends, or is elongated, along a Y axis. The X axis, Y axis, Z axis are mutually transverse to each other. In some embodiments, the X axis, Y axis, Z axis are mutually perpendicular to each other. The top semiconductor device 10U further comprises a channel region configured by nanosheets 26U which extend along the X axis and connect the source/drains 62U. In the example configuration in FIG. 1A, the top semiconductor device 10U comprises two nanosheets 26U. Other numbers of nanosheets per transistor are within the scopes of various embodiments. The top semiconductor device 10U comprises a gate dielectric layer 78 extending around each of the nanosheets 26U, and electrically isolating the gate 80U from the nanosheets 26U. The gate 80U extends around the gate dielectric layer 78 and nanosheets 26U in a configuration referred to as a gate-all-around (GAA) configuration. Other gate configurations are within the scopes of various embodiments.

The bottom semiconductor device 10L comprises a gate 80L, source/drains 62L, a channel region configured by nanosheets 26L, and a gate dielectric layer 78 extending around each of the nanosheets 26L. The gate 80L, source/drains 62L, and nanosheets 26L correspond to the gate 80U, source/drains 62U, and nanosheets 26U. The gate 80U, source/drains 62U, and nanosheets 26U correspondingly overlap the gate 80L, source/drains 62L, and nanosheets 26L along the Z axis. In the example configuration in FIG. 1A, the source/drains 62U, 62L are epitaxy structures of different conductivity types. For example, the source/drains 62L are P-type epitaxy structures, and the source/drains 62U are N-type epitaxy structures.

The stacked structure 10 further comprises an intermediate layer 90 between the gate 80U and gate 80L. In some embodiments, the intermediate layer 90 is a dielectric layer electrically isolating the gate 80U from the gate 80L, in a configuration referred to as an isolated gate configuration in which the gate 80U and gate 80L are controllable independently from each other. In at least one embodiment, the gate 80U and the gate 80L in an isolated gate configuration are still electrically coupled to each other by a conductor, e.g., a gate local interconnect (MGLI). In some embodiments, the intermediate layer 90 is a conductive layer electrically coupling the gate 80U to the gate 80L, in a configuration referred to as a connected gate configuration in which the electrically coupled gate 80U and gate 80L form a common gate for both top semiconductor device 10U and bottom semiconductor device 10L. In a connected gate configuration in accordance with some embodiments, the conductive intermediate layer 90 is formed integrally, and/or simultaneously, with the gate 80U and gate 80L in a single GAA structure.

As can be seen from FIG. 1A, in one or more embodiments, the stacking of the top semiconductor device 10U over the bottom semiconductor device 10L saves about 50% of the required chip area, compared to other approaches without stacking of semiconductor devices. In some embodiments, it is possible to manufacturing an IC device comprising multiple device stacks by CFET processes, with little or no changes to the manufacturing processes.

FIG. 1B is a schematic perspective view, and FIGS. 1C-1F are schematic cross-sectional views, in an X-Z plane, of an IC device 100 at various stages in a manufacturing process, in accordance with some embodiments. The IC device 100 comprises a plurality of device stacks corresponding to the device stack 100A. For simplicity, corresponding components in FIGS. 1A-1F are designated by the same reference numerals. In some embodiments, additional operations are provided before, during, and/or after the manufacturing process described with respect to FIGS. 1B-1F, and/or one or more of the described operations are replaced or eliminated, and or the order of the operations is interchangeable.

Referring to FIG. 1B, the manufacturing process starts from a substrate 20. In at least one embodiment, the substrate 20 is a semiconductor substrate. In some embodiments, the substrate 20 includes a single crystalline semiconductor layer on at least the surface of the substrate 20. Example materials of the substrate 20 include, but are not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). For example, the substrate 20 is a Si substrate. In some embodiments, the substrate 20 is a silicon-on-insulator (SOI) substrate, which includes an insulating layer disposed between two silicon layers. In at least one embodiment, the insulating layer is an oxide layer.

A multilayer structure 22 is formed over the substrate 20. In FIG. 1B, the multilayer structure 22 is illustrated in a state after formation of fins, as described herein. The multilayer structure 22 comprises alternatingly arranged first semiconductor layers 24A, 24B and second semiconductor layers 26U, 26L. The second semiconductor layers 26U, 26L correspond to the nanosheets described with respect to FIG. 1A, and are referred to herein by the same reference numerals of the nanosheets, for simplicity. The first semiconductor layers 24A, 24B and the second semiconductor layers 26U, 26L comprise semiconductor materials having different etch selectivity and/or oxidation rates. For example, the first semiconductor layers 24A, 24B comprise SiGe, and the second semiconductor layers 26U, 26L comprise Si. In some embodiments, the first and second semiconductor layers 24A, 24B, 26U, 26L are formed by a deposition process, such as epitaxy. For example, epitaxial growth of the layers of the multilayer structure 22 is performed by a molecular beam epitaxy (MBE) process, a metalorganic chemical vapor deposition (MOCVD) process, and/or other suitable epitaxial growth processes.

Subsequent to the formation of the multilayer structure 22, fins 28 are formed. Each fin 28 comprises a substrate portion 21 of the substrate 20, and a portion 34 of the multilayer structure 22. The portion 34 of the multilayer structure 22 is sometimes referred to as a stack of semiconductor layers 34. In some embodiments, the fins 28 are fabricated using suitable processes, such as double-patterning or multi-patterning processes. For example, in one or more embodiments, a sacrificial layer is formed over a substrate and patterned using a photolithography process. Spacers are formed alongside the patterned sacrificial layer using a self-aligned process. The sacrificial layer is then removed, and the remaining spacers are then used to pattern the fins 28 by etching the multilayer structure 22 and the substrate 20. Example etch processes include, but are not limited to, dry etch, wet etch, reactive ion etch (RIE), and/or other suitable processes. In FIG. 1B, two fins 28 are illustrated; however, the number of the fins is not limited to two. The fins 28 extend, or are elongated, along the X axis.

A shallow trench isolation (STI) 32 of an insulating material is formed over the substrate 20 and in trenches (not numbered) between the fins 28. For example, the insulating material is deposited over the substrate 20 and the fins 28. Example insulating materials of the STI 32 include, but are not limited to, silicon oxide, fluorine-doped silicate glass (FSG), silicon nitride, silicon oxynitride (SiON), SiOCN, SiCN, a low-k dielectric material, or the like. The deposition of the insulating material includes a suitable method, such as low-pressure chemical vapor deposition (LPCVD), plasma enhanced CVD (PECVD) or flowable CVD (FCVD). Then, a planarization operation, such as a chemical mechanical polishing (CMP) process and/or an etch-back process, is performed such that the tops of the fins 28 are exposed from the insulating material. A portion of the insulating material between adjacent fins 28 is removed. The remaining portion of the insulating material configures the STI 32. The partial removal of the insulating material includes dry etch, wet etch, or the like.

A sacrificial gate dielectric layer 36, a sacrificial gate electrode layer 38, and a mask structure 40 are deposited over the STI 32 and fins 28. The sacrificial gate dielectric layer 36 comprises one or more layers of dielectric material, such as SiO2, SiN, a high-k dielectric material, and/or other suitable dielectric material. In some embodiments, the sacrificial gate dielectric layer 36 is deposited by a CVD process, a sub-atmospheric CVD (SACVD) process, a FCVD process, an atomic layer deposition (ALD) process, a physical vapor deposition (PVD) process, or other suitable process. In at least one embodiment, the sacrificial gate electrode layer 38 comprises polycrystalline silicon (polysilicon). In some embodiments, the mask structure 40 comprises a multilayer structure. In some embodiments, the sacrificial gate electrode layer 38 and the mask structure 40 are formed by one or more processes such as layer deposition, for example, CVD (including both LPCVD and PECVD), PVD, ALD, thermal oxidation, e-beam evaporation, or other suitable deposition techniques. A structure 100B is obtained.

Referring to FIG. 1C, sacrificial gate stacks 42 are formed by one or more pattern and/or etch processes performed on the deposited sacrificial gate dielectric layer 36, sacrificial gate electrode layer 38, and mask structure 40 of the structure 100B. An example pattern process comprises a lithography process. An example etch process comprises dry etch (e.g., RIE), wet etch, other etch methods, and/or combinations thereof. Each sacrificial gate stack 42 comprises a portion of each of the sacrificial gate dielectric layer 36, sacrificial gate electrode layer 38, and mask structure 40. The sacrificial gate stacks 42 extend, or are elongated, along the Y axis. In FIG. 1C, three sacrificial gate stacks 42 are illustrated; however, the number of the sacrificial gate stacks 42 is not limited to two.

Spacers 44 are formed on sidewalls of the sacrificial gate stacks 42. For example, the spacers 44 are formed by first depositing a conformal layer that is subsequently etched back to form the spacers 44. The spacers 44 comprises a dielectric material, such as silicon oxide, silicon nitride, silicon carbide, silicon oxynitride, SiCN, silicon oxycarbide, SiOCN, and/or combinations thereof. In some embodiments, the spacers 44 comprise multiple layers.

Exposed portions of the stacks of semiconductor layers 34 of the fins 28 not covered by the sacrificial gate stacks 42 and the spacers 44 are selectively removed, e.g., by one or more suitable etch processes, such as dry etch, wet etch, or a combination thereof, to form trenches 46. In FIG. 1C, a lower most one of the second semiconductor layers 26U and an uppermost one of the second semiconductor layers 26L are designated as middle second semiconductor layers 26M which sandwich therebetween a middle first semiconductor layer 24B. The middle second semiconductor layers 26M and the middle first semiconductor layer 24B are not configured to form channel regions of the top semiconductor device 10U and bottom semiconductor device 10L. Edge portions of the first semiconductor layers 24A, 24B and second semiconductor layers 26U, 26L, 26M are exposed in the trenches 46. The trenches 46 also expose portions of the substrate portion 21. A structure 100C is obtained.

Referring to FIG. 1D, the exposed edge portions of the first semiconductor layers 24A are removed. In some embodiments, the removal comprises a selective wet etch process. The selective wet etch process further completely (or substantially completely) removes the first semiconductor layer 24B in the middle of the stack of semiconductor layers 34. For example, in embodiments where the first semiconductor layers 24A, 24B comprise SiGe, and the second semiconductor layers 26U, 26L, 26M comprise Si, a selective wet etch is configured to etch the first semiconductor layer 24B at a highest etch rate, the first semiconductor layers 24A at a second highest etch rate, and the second semiconductor layers 26U, 26L, 26M at a slowest etch rate. As a result, the exposed edge portions of the first semiconductor layers 24A and an entirety (or substantially an entirety) of the first semiconductor layer 24B are removed, whereas the second semiconductor layers 26U, 26L, 26M are substantially unchanged.

A dielectric material is deposited over and into the spaces created by the removal of the first semiconductor layer 24B and the partial removal of the edge portions of the first semiconductor layers 24A. The dielectric material filling in the spaces created by the partial removal of the edge portions of the first semiconductor layers 24A configures inner spacers 54. The dielectric material filling in the space created by the removal of the first semiconductor layer 24B configures an inner isolation structure 56. Examples of the dielectric material forming the inner spacers 54 and inner isolation structure 56 include, but are not limited to, a low-k dielectric material, such as SiO2, SiN, SiCN, SiOC, or SiOCN, or a high-k dielectric material, such as HfO2, ZrOx, ZrAlOx, HfAlOx, HfSiOx, AlOx, or other suitable dielectric material. In some embodiments, the inner spacers 54 and inner isolation structure 56 comprise different dielectric materials. In an example process, the inner spacers 54 and inner isolation structure 56 are formed by depositing a conformal layer of the dielectric material, using a conformal deposition process, such as ALD, followed by an anisotropic etching to remove portions of the conformal layer other than the inner spacers 54 and inner isolation structure 56.

Source/drain 62L are formed over, and in contact with, the exposed portions of the substrate portions 21, and exposed edge portions of the second semiconductor layers 26L. In the example configuration in FIG. 1D, the source/drains 62L comprise epitaxy structures and are sometimes referred to as source/drain epitaxy structures 62L. In some embodiments, the source/drain epitaxy structures 62L comprise one or more layers of Si, SiGe, Ge to configure a P-type bottom semiconductor device. Example epitaxial growth processes for growing the source/drain epitaxy structures 62L include, but are not limited to, CVD, ALD, MBE. In some embodiments, source/drain epitaxy structures 62L are grown to a height above the uppermost second semiconductor layer 26L, and then top portions of the source/drain epitaxy structures 62L are partially removed, e.g., by a dry etch or wet etch, so that upper surfaces of the remaining source/drain epitaxy structures 62L are at a level of the uppermost first semiconductor layer 24A immediately under the lower middle second semiconductor layer 26M, as illustrated in FIG. 1D.

A liner 63 is formed at least over the upper surfaces of the source/drain epitaxy structures 62L, and exposed side faces of the middle second semiconductor layers 26M, inner isolation structure 56. In some embodiments, the liner 63 comprises Si. In an example process, the liner 63 is a conformal layer formed by a conformal process, such as an ALD process.

A dielectric material 68 is formed over the liner 63 and over the source/drain epitaxy structures 62L. In some embodiments, the dielectric material 68 comprises the same material as the STI 32 and/or is formed by the same method as the STI 32. The liner 63 and dielectric material 68 are removed outside the trenches 46, and partially removed inside the trenches 46, e.g., by a dry etch or wet etch. As a result, upper surfaces of the liner 63 and dielectric material 68 are at a level of the lowermost first semiconductor layer 24A immediately above the upper middle second semiconductor layer 26M, as illustrated in FIG. 1D. The liner 63 and dielectric material 68 configure an isolation structure between the source/drain 62L and source/drains 62U to be subsequently formed thereover.

Source/drain 62U are formed over, and in contact with, the upper surfaces of the liner 63 and dielectric material 68, and exposed edge portions of the second semiconductor layers 26U. In the example configuration in FIG. 1D, the source/drains 62U comprise epitaxy structures and are sometimes referred to as source/drain epitaxy structures 62U. The source/drain epitaxy structures 62U are of a conductivity type different from that of the source/drain epitaxy structures 62L. In some embodiments, the source/drain epitaxy structures 62U are manufactured by the same or similar manufacturing processes as/to the source/drain epitaxy structures 62L. In at least one embodiment, the source/drain epitaxy structures 62U have the same configuration, e.g., the same size, shape, height, as the source/drain epitaxy structures 62L. In an example, the source/drain epitaxy structures 62U comprise one or more layers of Si, SiP, SiC and SiCP to configure an N-type top semiconductor device. In some embodiments, source/drain epitaxy structures 62U are grown to a height above the sacrificial gate dielectric layer 36, and then top portions of the source/drain epitaxy structures 62U are partially removed, e.g., by a dry etch or wet etch, so that upper surfaces of the remaining source/drain epitaxy structures 62U are at a level of the sacrificial gate dielectric layer 36, as illustrated in FIG. 1D. This is an example, and a height of the source/drain epitaxy structures 62U is controllable depending on application and/or process requirements.

A contact etch stop layer (CESL) 70 is formed over the source/drain epitaxy structures 62U. Example materials of the CESL 70 include, but are not limited to, silicon nitride, silicon carbon nitride, silicon oxynitride, carbon nitride, silicon oxide, silicon carbon oxide, the like, or a combination thereof. The CESL 70 is formed by CVD, PECVD, ALD, or any suitable deposition technique.

An interlayer dielectric (ILD) layer 72 is formed over the CESL 70. Example materials of the ILD layer 72 include, but are not limited to, tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 72 is deposited by a PECVD process or other suitable deposition technique. A structure 100D is obtained.

Referring to FIG. 1E, a planarization process, such as a CMP process, is performed to remove the mask structure 40 and expose the sacrificial gate electrode layer 38. The planarization process also removes portions of the ILD layer 72 and the CESL 70.

The exposed sacrificial gate electrode layer 38 and the sacrificial gate dielectric layer 36 are removed, e.g., by one or more suitable processes, such as dry etch, wet etch, or a combination thereof.

Next, the first semiconductor layers 24A are removed, e.g., by any suitable processes, such as dry etch, wet etch, or a combination thereof. The removal of the first semiconductor layers 24A exposes the inner spacers 54 and the second semiconductor layers 26U, 26L, and creates spaces between and around exposed portions of the second semiconductor layers 26U, 26L not covered by the inner spacers 54. The exposed portions of the second semiconductor layers 26U, 26L configure the nanosheets 26U, 26L described with respect to FIG. 1A. The middle second semiconductor layers 26M and inner isolation structure 56 are covered by the liner 63 and dielectric material 68, and are substantially unaffected by the removal of the first semiconductor layers 24A.

A gate dielectric layer 78 is formed over and around each of the nanosheets 26U, 26L. In some embodiments, the gate dielectric layer 78 comprises the same material as the sacrificial gate dielectric layer 36. In some embodiments, the gate dielectric layer 78 comprises a high-k dielectric material. In some embodiments, the gate dielectric layer 78 is formed by a conformal process, such as an ALD process.

A gate electrode material is formed over and around the gate dielectric layers 78, and the nanosheets 26U, 26L. The gate electrode material surrounding each of the nanosheets 26U configures the gate 80U. The gate electrode material surrounding each of the nanosheets 26L configures the gate 80L. In some embodiments, the gate electrode material comprises multiple gate electrode layers. Example gate electrode materials include, but are not limited to, polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. In some embodiments, the gate electrode material comprises a P-type gate electrode layer, such as TiN, TaN, TiTaN, TiAlN, WCN, W, Ni, Co, or other suitable material, for configuring P-type bottom semiconductor devices. In at least one embodiment, the gate electrode material comprises an N-type gate electrode layer, such as TiAlC, TaAlC, TiSiAlC, TiC, TaSiAlC, or other suitable material, for configuring N-type top semiconductor devices. Example processes for depositing the gate electrode material include, but are not limited to, PVD, CVD, ALD, electro-plating, or other suitable methods.

In some embodiments, each of the gate 80U and gate 80L comprises a corresponding GAA structure, and the gate 80U and gate 80L are physically and electrically separated from each other by the middle second semiconductor layers 26M and inner isolation structure 56. In some embodiments, a combination of the middle second semiconductor layers 26M and inner isolation structure 56 corresponds to the intermediate layer 90 being a dielectric material in an isolated gate configuration. In at least one embodiment, the gate 80U and the gate 80L in an isolated gate configuration are still electrically coupled to each other by a conductor, e.g., an MGLI interconnect. In some embodiments, the gate 80U and gate 80L are integral parts of a GAA structure which extends around each of the nanosheets 26U, 26L, and configures a common gate for both top semiconductor device and bottom semiconductor device. The formation of the gate 80U and gate 80L completes the formation of the top semiconductor device 10U and bottom semiconductor device 10L. An ILD layer 92 similar to the ILD layer 72 is deposited over the gate 80U, and a planarization process, such as a CMP, is performed. A structure 100E is obtained.

Referring to FIG. 1F, openings are formed in the ILD layer 72 to expose the source/drain epitaxy structures 62U. A silicide layer 94 is formed over the exposed source/drain epitaxy structures 62U, and then source/drain contacts 96U are form in each opening and over the silicide layer 94. Source/drain contacts (or source/drain contact structures) are sometimes referred to as metal-to-device (MD) contacts. Source/drain contacts of top semiconductor devices are sometimes referred to as MD contacts or top contact structures. Source/drain contacts of bottom semiconductor devices are sometimes referred to as BMD contacts or bottom contact structures. For simplicity, an MD contact, or a contact structure, herein refers to either an MD contact at the upper layer or a BMD contact at the lower layer, unless specified otherwise. Example materials of the source/drain contacts 96U include, but are not limited to, Ru, Mo, Co, Ni, W, Ti, Ta, Cu, Al, TiN and TaN. The source/drain contacts 96U are formed by any suitable process, such as PVD, ECP, or CVD.

Dielectric layers 104, 106 are deposited over the MD contacts 96U and ILD layer 92. Various vias 108, 110 are formed by etching via openings in the dielectric layers 104, 106 and ILD layer 92, and then filling the via openings with a conductive material, such as a metal. A via over and in electrical contact with an MD contact is sometimes referred to as via-to-device (VD) via. A via over and in electrical contact with a gate is sometimes referred to as via-to-gate (VG) via. In the example configuration in FIG. 1F, the via 108 is a VG via which is over the gate 80U, and the vias 110 are VD vias correspondingly over the MD contacts 96U. VG and VD vias for bottom semiconductor devices are sometimes correspondingly referred to as BVG and BVD vias. A resulting structure 112 comprising various semiconductor devices formed over a front side (or upper side) of the substrate 20 and the corresponding MD contacts, VG and VD vias is obtained.

A redistribution structure 114 is formed over the VD, VG vias 110, 108 of the structure 112. The redistribution structure 114 comprises a plurality of metal layers 118A-118C and via layers 117A, 117B sequentially and alternatingly formed over the VD, VG vias 110, 108. The redistribution structure 114 further comprises various interlayer dielectric (ILD) layers 116 in which the metal layers and via layers are embedded. The metal layers and via layers of the redistribution structure 114 are configured to electrically couple various semiconductor devices, or circuits of the IC device 100 with each other, and/or with external circuitry. In the redistribution structure 114, the lowermost metal layer 118A immediately over and in electrical contact with the VD, VG vias 110, 108 is an M0 (metal-zero) layer, a next metal layer 118B immediately over the M0 layer is an M1 layer, a next metal layer 118C immediately over the M1 layer is an M2 layer, or the like.

Conductive patterns in the M0 layer are referred to as M0 conductive patterns, conductive patterns in the M1 layer are referred to as M1 conductive patterns, or the like. A via layer Vn is arranged between and electrically couple the Mn layer and the Mn+1 layer, where n is an integer from zero and up. For example, the via layer 117A is a via-zero (V0) layer which is the lowermost via layer arranged between and electrically couple the M0 layer 118A and the M1 layer 118B. The next via layer 117B is a V1 layer which is the via layer arranged between and electrically couple the M1 layer 118B and the M2 layer 118C. Vias in the V0 layer are referred to as V0 vias, vias in the V1 layer are referred to as V1 vias, or the like. For simplicity, metal layers and via layers in the redistribution structure 114 are not fully illustrated in FIG. 1F. The redistribution structure 114 and interconnects therein are formed over the front side of the substrate 20, and are sometimes referred to as the front side redistribution structure and front side interconnects. A structure 100F is obtained, as illustrated in FIG. 1F.

In some embodiments, the fabrication of the IC device 100 further comprises forming various features and/or structures on the back side (e.g., the lower side in FIG. 1F) of the substrate 20. In an example manufacturing process, the structure 100F is flipped over and temporarily bonded to a carrier (not shown). Wafer thinning is performed from the back side (now facing upward) to remove a portion of the substrate 20. For example, as illustrated in FIG. 1F, a substrate portion 130 of the substrate 20 remains as a result of the wafer thinning on the back side. In some embodiments, the wafer thinning process includes a grinding operation, a polishing operation (such as, chemical mechanical polishing (CMP)), or the like. In at least one embodiment, the substrate 20 is completely removed, and a new substrate (not shown), e.g., an insulation substrate, is formed over the bottom semiconductor device 10L. Next, various BMD contacts, BVG vias and BVD vias are formed in manners similar to those correspondingly described with respect to the formation of MD contacts, VG vias and VD vias. A back side redistribution structure is formed, in a manner similar to the redistribution structure 114. The back side redistribution structure comprises various back side metal layers and various back side via layers arranged alternatingly in the thickness direction, i.e., along the Z axis. The back side redistribution structure further comprises various interlayer dielectric (ILD) layers in which the back side metal layers and back side via layers are embedded.

The back side metal layer immediately adjacent the bottom semiconductor device 10L is a back side M0 (BM0) layer, a next back side metal layer is a back side M1 (BM1) layer, or the like. A back side via layer BVn is arranged between and electrically couples the BMn layer and the BMn+1 layer, where n is an integer from zero and up. For example, a via layer BV0 is the back side via layer arranged between and electrically couples the BM0 layer and the BM1 layer. Other back side via layers are BV1, BV2, or the like. Conductive patterns in the BM0 layer are referred to as BM0 conductive patterns, conductive patterns in the BM1 layer are referred to as BM1 conductive patterns, or the like. Vias in the BV0 layer are referred to as BV0 vias, vias in the BV1 layer are referred to as BV1 vias, or the like. Although the described manufacturing processes include formation of nanosheet devices in one or more embodiments, other types of devices, e.g., nanowire, FinFET, planar, or the like, are within the scopes of various embodiments. The described manufacturing processes and/or orders of operations are examples. Other manufacturing processes and/or orders of operations are within the scopes of various embodiments.

In some embodiments, the formation of top and bottom semiconductor devices, including gates, channel regions and source/drains, is referred to as a front-end-of-line (FEOL) fabrication, whereas the formation of front side and back side redistribution structures is referred to as a back-end-of-line (BEOL) fabrication to provide routing for the semiconductor devices. The formation of various features between FEOL and BEOL fabrications are referred to as a middle-of-line (MOL) fabrication. Example of MOL features include, but are not limited to, MD contacts, BMD contacts, via interconnects such as power vias and/or power walls described herein, dielectric structures corresponding to cut-metal-gate (CMG) regions, various vias coupled to gates, MD contacts, BMD contacts and/or via interconnects, or the like.

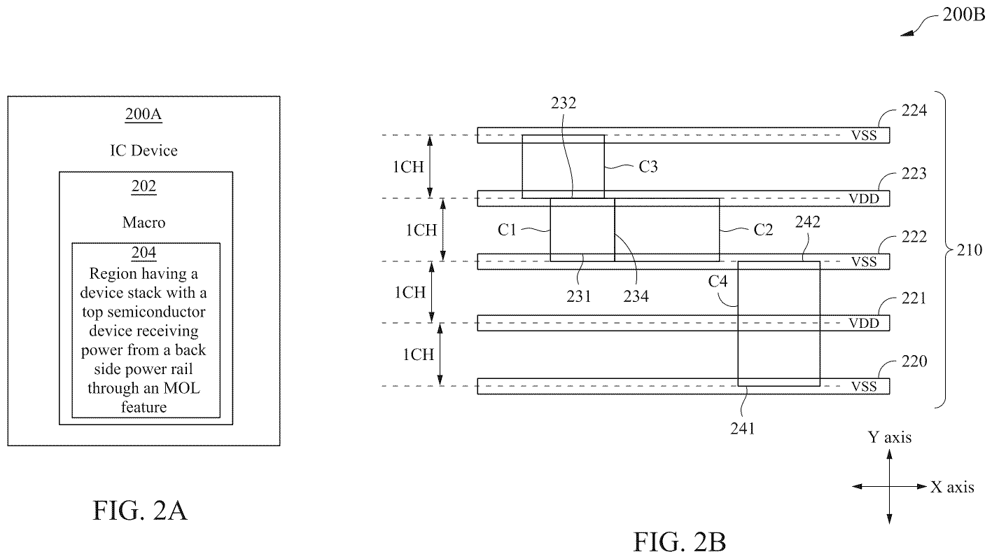

FIG. 2A is a block diagram of an IC device 200A, in accordance with some embodiments.

In FIG. 2A, the IC device 200A comprises, among other things, a macro 202. In some embodiments, the macro 202 comprises one or more of a memory, a power grid, a cell or cells, an inverter, a latch, a buffer and/or any other type of circuit arrangement that may be represented digitally in a cell library. In some embodiments, the macro 202 is understood in the context of an analogy to the architectural hierarchy of modular programming in which subroutines/procedures are called by a main program (or by other subroutines) to carry out a given computational function. In this context, the IC device 200A uses the macro 202 to perform one or more given functions. Accordingly, in this context and in terms of architectural hierarchy, the IC device 200A is analogous to the main program and the macro 202 is analogous to subroutines/procedures. In some embodiments, the macro 202 is a soft macro. In some embodiments, the macro 202 is a hard macro. In some embodiments, the macro 202 is a soft macro which is described digitally in register-transfer level (RTL) code. In some embodiments, synthesis, placement and routing have yet to have been performed on the macro 202 such that the soft macro can be synthesized, placed and routed for a variety of process nodes. In some embodiments, the macro 202 is a hard macro which is described digitally in a binary file format (e.g., Graphic Database System II (GDSII) stream format), where the binary file format represents planar geometric shapes, text labels, other information and the like of one or more layout-diagrams of the macro 202 in hierarchical form. In some embodiments, synthesis, placement and routing have been performed on the macro 202 such that the hard macro is specific to a particular process node.

The macro 202 includes a region 204 which comprises a device stack with a top semiconductor device receiving power from a back side power rail through an MOL feature. Examples of a device stack and a top semiconductor device are described with respect to FIG. 1A. Examples of a back side power rail are described herein, e.g., with respect to FIG. 2B. In some embodiments, the region 204 comprises a substrate having circuitry formed thereon, in an FEOL fabrication. Furthermore, above and/or below (e.g., on a front side and/or a back side of) the substrate, the region 204 comprises various metal layers that are stacked over and/or under insulating layers in a BEOL fabrication. The BEOL provides a power network and/or routing for circuitry of the IC device 200A, including the macro 202 and the region 204. The region 204 further comprises one or more MOL features electrically coupling a back side power rail in the power network to a top semiconductor device, as described herein.

FIG. 2B is a schematic view of a layout 200B an IC device, in accordance with some embodiments. In some embodiments, the layout 200B corresponds to the IC device 200A. For simplicity, various features of the layout 200B are omitted in FIG. 2B. In at least one embodiment, the layout 200B is stored on a non-transitory computer-readable recording medium.

The layout 200B comprises a power delivery structure and one or more functional circuits coupled to and powered by power delivered through the power delivery structure. In the example configuration in FIG. 2B, the power delivery structure comprises a power delivery network 210, and the one or more functional circuits are schematically represented by a plurality of cells C1-C4.

The power delivery network 210 comprises a plurality of power rails 220-224 elongated along a first axis (i.e., X axis) and spaced, by a center-to-center interval CH (cell height), from each other along a second axis (Y axis) transverse to the first axis. In at least one embodiment, the Y axis is perpendicular to the X axis. In some embodiments, the power delivery network 210 is a back side power delivery network to be arranged on a back side of an IC device which further includes a front side opposite to the back side in a thickness direction of the IC device. The power rails 220-224 of the power delivery network 210 are configured to provide a first power supply voltage, and a second power supply voltage different from the first power supply voltage. For example, the first power supply voltage is one of VSS and VDD, and the second power supply voltage is the other of VSS and VDD. Power rails configured to provide VSS are sometimes referred to herein as VSS power rails, and power rails configured to provide VDD are sometimes referred to herein as VDD power rails. VDD power rails and VSS power rails are alternatingly arranged along the Y axis. In the example configuration in FIG. 2B, the power rails 220, 222, 224 are VSS power rails which are alternatingly arranged with VDD power rails comprising the power rails 221, 223. In some embodiments, power supply voltages, e.g., VSS and VDD, are provided to the power rails 220-224 through one or more back side metal layers and via layers as described herein.

In some embodiments, the power delivery structure further comprises a front side power delivery network (not shown) on the front side of the IC device. In at least one embodiment, the front side power delivery network comprises one or more power rails extending along the X axis, and arranged in a front side metal layer, as described herein. The power delivery structure further comprises power tap structures or circuits (not shown) configured to deliver VDD and/or VSS from the power delivery network 210 to the front side power delivery network. In some embodiments, the power tap structures are distributed uniformly, or substantially uniformly, across an area of the layout 200B.

The cells C1-C4 correspond to one or more functional circuits of the IC device. The functional circuits are configured to perform one or more functions of the IC device. In some embodiments, the functional circuits comprises one or more active devices, passive devices, logic circuits, or the like. Examples of logic circuits include, but are not limited to, AND, OR, NAND, NOR, XOR, INV, AND-OR-Invert (AOI), OR-AND-Invert (OAI), MUX, Flip-flop, BUFF, Latch, delay, clock, memory, or the like. Example memory cells include, but are not limited to, a static random access memory (SRAM), a dynamic RAM (DRAM), a resistive RAM (RRAIVI), a magnetoresistive RAM (MRAM), a read only memory (ROM), or the like. Examples of active devices or active elements include, but are not limited to, transistors, diodes, or the like. Examples of passive elements include, but are not limited to, capacitors, inductors, fuses, resistors, or the like. In some embodiments, the functional circuits comprise device stacks of semiconductor devices, or CFET devices, as described herein.

The functional circuits are electrically coupled to and powered by the power rails 220-224 and/or one or more power rails of a front side power delivery network. In some embodiments, a front side power delivery network and associated power tap structures are omitted, and the functional circuits of the IC device are coupled to receive power (e.g., VDD and VSS) only from the power delivery network 210 on the back side of the IC device.

In some embodiments, to generate the layout 200B, various cells, such as the cells C1-C4, are placed, in a placement operation performed by an EDA tool or an automated placement and routing (APR) system, over the power delivery network 210. The cells C1-C4 are schematically represented in FIG. 2B by their corresponding boundaries. One or more cells are placed in the placement operation with their boundaries in abutment with the boundaries of one or more further cells. For example, in the X axis, the cell C1 is placed in abutment with the cell C2 along a common edge 234. In the Y axis, the cell C1 is placed in abutment with the cell C3 along a common edge 232. Cells are not always placed (or placeable) in abutment. For example, the cell C4 is placed to be spaced from the cell C2 along the X axis. The described placement operation is an example. Other placement operations are within the scopes of various embodiments.

A cell is placed over one or more of the power rails 220-224 to receive VDD and/or VSS from the underlying power rails. In some embodiments, a cell is placed with the corresponding boundary over and coinciding with center lines of two power rails. A cell height of the cell along the Y axis corresponds to a center-to-center distance between the two power rails. For example, in FIG. 2B, the boundary of the cell C1 has edges 231, 232 over and coinciding correspondingly with the center lines of the power rails 222, 223. As a result, the cell C1 has a cell height of 1 CH (single cell height) being the center-to-center distance between the power rails 222, 223. The functional circuit in the cell C1 is configured to receive VSS from the power rail 222, and VDD from the power rail 223. For another example, the boundary of the cell C4 has edges 241, 242 over and coinciding correspondingly with the center lines of the power rails 220, 222. As a result, the cell C4 has a cell height of 2 CH (double cell height) being the center-to-center distance between the power rails 220, 222. The cell C4 is further over the power rail 221. The functional circuit in the cell C4 is configured to receive VSS from the power rails 220, 222, and VDD from the power rail 221. The described cells with single cell height or double cell height are examples. Other cells with greater cell heights, e.g., 3 CH, 4 CH, or the like, are within the scopes of various embodiments.

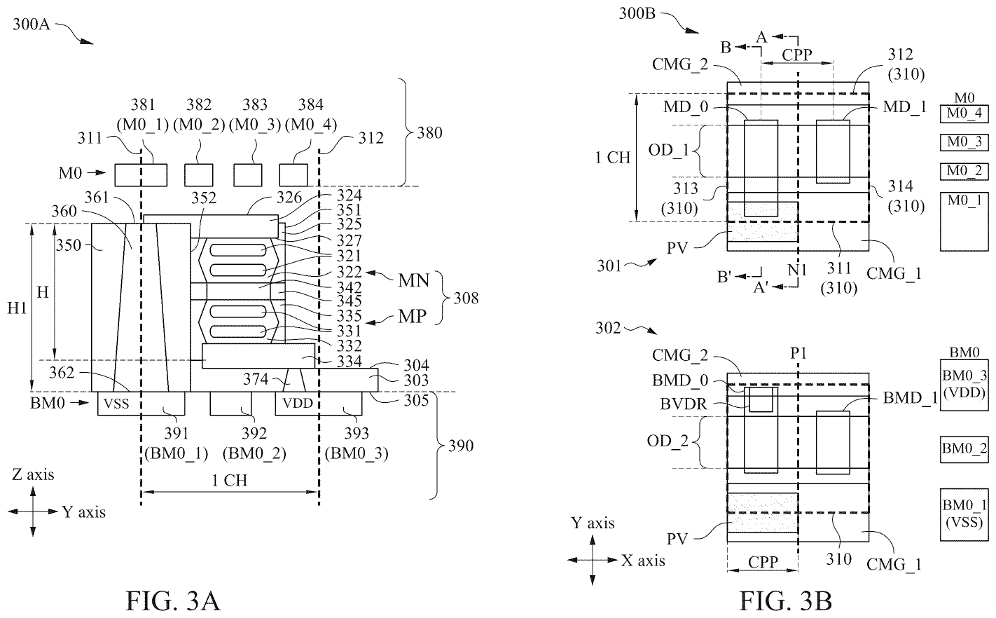

FIG. 3A is a schematic cross-sectional view of a circuit region of an IC device 300A, in accordance with some embodiments. In some embodiments, the IC device 300A corresponds to one or more of the IC devices 100, 200A and the layout 200B. In at least one embodiment, FIG. 3A corresponds to a cross-sectional view taken along the Y axis across a cell, e.g., the cell C1, in FIG. 2B.

As illustrated in FIG. 3A, the IC device 300A comprises a substrate 303 having a front side 304, and a back side 305 opposite to the front side 304 in a thickness direction, i.e., Z axis, of the substrate 303. In some embodiments, the substrate 303 comprises a semiconductor material, such as silicon, silicon germanium (SiGe), gallium arsenic, or other suitable semiconductor materials. In some embodiments, the substrate 303 comprises a dielectric material, such as silicon nitride, silicon oxide, ceramic, glass, or other suitable materials. In some embodiments, the substrate 303 comprises a multi-layer structure. In some embodiments, the substrate 303 is omitted, or comprises an insulation layer that replaces an initial semiconductor bulk used during manufacture. In at least one embodiment, the substrate 303 corresponds to one or more substrates described with respect to FIGS. 1A-1F.

The IC device 300A further comprises a device stack 308 comprising a bottom semiconductor device MP, and a top semiconductor device MN stacked over the bottom semiconductor device MP along the thickness direction, i.e., the Z axis. In some embodiments, the device stack 308 corresponds to the device stack 100A, and/or is manufactured by one or more processes or operations described with respect to FIGS. 1B-1F. The device stack 308 is configured over the front side 304 of the substrate 303.

In the example configuration in FIG. 3A, the top semiconductor device MN is an N-type semiconductor device and the bottom semiconductor device MP is a P-type semiconductor device, which together configure the device stack 308 as a CFET device. Each of the top semiconductor device and bottom semiconductor device comprises a channel which is arranged in a corresponding active region. For example, a channel 321 of the top semiconductor device MN comprises a semiconductor material, such as Si, in a corresponding top active region (not numbered), and is configured as at least one N-type nanosheet. In some embodiments, the channel 321 comprises multiple N-type nanosheets (two nanosheets are illustrated in the example configuration in FIG. 3A) stacked over, while being spaced from, each other in the thickness direction. Similarly, a channel 331 of the bottom semiconductor device MP comprises a semiconductor material, such as Si, in a corresponding bottom active region (not numbered) below the top active region, and is configured as at least one P-type nanosheet. In some embodiments, the channel 331 comprises multiple P-type nanosheets (two nanosheets are illustrated in the example configuration in FIG. 3A) stacked over, while being spaced from, each other in the thickness direction. The described channel material and nanosheets are examples. Other channel materials and/or channel types, such as nanowire, FinFET, planar, or the like, are within the scopes of various embodiments.

Each of the top semiconductor device and bottom semiconductor device further comprises a gate. For example, the top semiconductor device MN comprises a gate 325 which is an all-around gate extending around the channel 321, and the bottom semiconductor device MP comprises a gate 335 which is an all-around gate extending around the channel 331. In the example configuration in FIG. 3A, the gates 325, 335 are electrically isolated from each other by a dielectric layer 345 in an isolated gate configuration as described herein. In at least one embodiment, the gates 325, 335 are electrically coupled to each other by a conductor, e.g., a gate local interconnect (MGLI) (not shown). In some embodiments, the gates 325, 335 are metal gates. Other gate materials, such as polysilicon, are within the scopes of various embodiments. In some embodiments, the gate material of the gate 325 and/or the gate 335 replaces a sacrificial material, such as SiGe, in the corresponding active region during a manufacturing process. The gates 325, 335 and the dielectric layer 345 (or an MGLI) together configure a gate structure of the device stack 308. It should be noted that the cross-sectional view in FIG. 3A is a combination of two cross-sectional views, i.e., one view along a cross-section A-A′ in FIG. 3B and including the gates 325, 335 and the dielectric layer 345, and another view along a cross-section B-B′ in FIG. 3B and including remaining features other than the gates 325, 335 and the dielectric layer 345.

Each top semiconductor device or bottom semiconductor device further comprises a gate dielectric (not shown) between the corresponding gate and channel. For example, a gate dielectric is between each of the gate 325 and the corresponding channel 321, and extends around the channel 321. Example materials of the gate dielectric include high-k dielectric materials, or the like.

Each top semiconductor device further comprises source/drains (sometimes referred to as top source/drains) in the corresponding top active region, and each bottom semiconductor device further comprises source/drains (sometimes referred to as bottom source/drains) in the corresponding bottom active region. For example, the top semiconductor device MN includes a source/drain 322, and the bottom semiconductor device MP includes a source/drain 332. The other source/drain of the top semiconductor device MN and the other source/drain of the bottom semiconductor device MP are not visible/shown in FIG. 3A. In some embodiments, source/drains of a semiconductor device are coupled to the corresponding channel, and are arranged in the same active region as a the channel.

For example, the source/drain 322 and the other source/drain (not shown) of the top semiconductor device MN are coupled by the channel 321, and are all in the top active region containing the channel 321. For another example, the source/drain 332 and the other source/drain (not shown) of the bottom semiconductor device MP are coupled by the channel 331, and are all in the bottom active region containing the channel 331.

In the example configuration in FIG. 3A, the IC device 300A further comprises a source/drain local interconnect (MDLI) 342 arranged between and electrically coupling the source/drains 322, 332. In some embodiments, the MDLI interconnect 342 is omitted, i.e., replaced by a dielectric material, to electrically isolate the source/drains 322, 332. In at least one embodiment, an MDLI interconnect other than the MDLI interconnect 342 is provided between and electrically couples the source/drains 322, 332. An example material of MDLI interconnects comprises a metal.

The IC device 300A further comprises MD contacts for the top semiconductor device MN, and BMD contacts for the bottom semiconductor device MP. For example, an MD contact 324, i.e., a top contact structure, is over and in electrical contact with the source/drain 322 of the top semiconductor device MN, whereas a BMD contact 334, i.e., a bottom contact structure, is under and in electrical contact with the source/drain 332 of the bottom semiconductor device MP. An MD contact (not shown) similar to the MD contact 324 is over and in electrical contact with the other source/drain of the top semiconductor device MN. A BMD contact (not shown) similar to the BMD contact 334 is under and in electrical contact with the other source/drain of the bottom semiconductor device MP.

The IC device 300A further comprises a dielectric structure 350 in contact with the gates 325, 335 along a surface 352. In some embodiments, the dielectric structure 350 corresponds to a cut-metal-gate (CMG) mask, or a cut-poly(silicon) (CPO) mask, or a similar cut-gate mask configured to define or configure the length of one or more gates. For simplicity, CMG, CPO and cut-gate are used interchangeably herein to designate such a gate length defining mask. The IC device 300A comprises a further dielectric structure (not shown for simplicity) similar to the dielectric structure 350, but on the other side of the gates 325, 335 along the Y axis, and in contact with the gates 325, 335 along a surface 351 opposite to the surface 352. The length of the gates 325, 335 is defined or configured by a distance along the Y axis between the dielectric structure 350 and the further dielectric structure. In the example configuration in FIG. 3A, the dielectric structure 350 and the further dielectric structure have corresponding center lines 311, 312. In some embodiments, the center lines 311, 312 correspond to center lines of corresponding power rails and/or edges of a boundary of a cell, as described with respect to FIG. 2B.

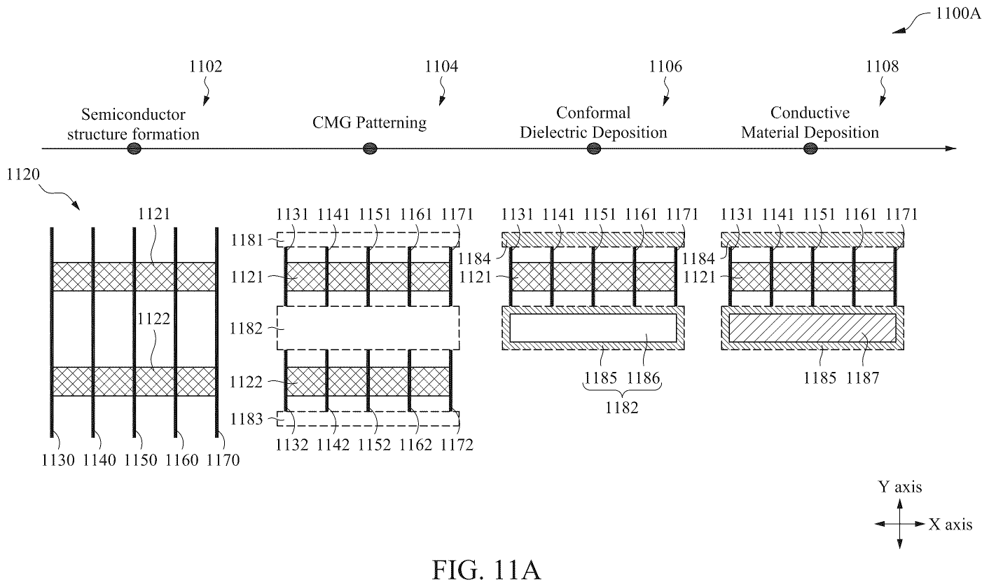

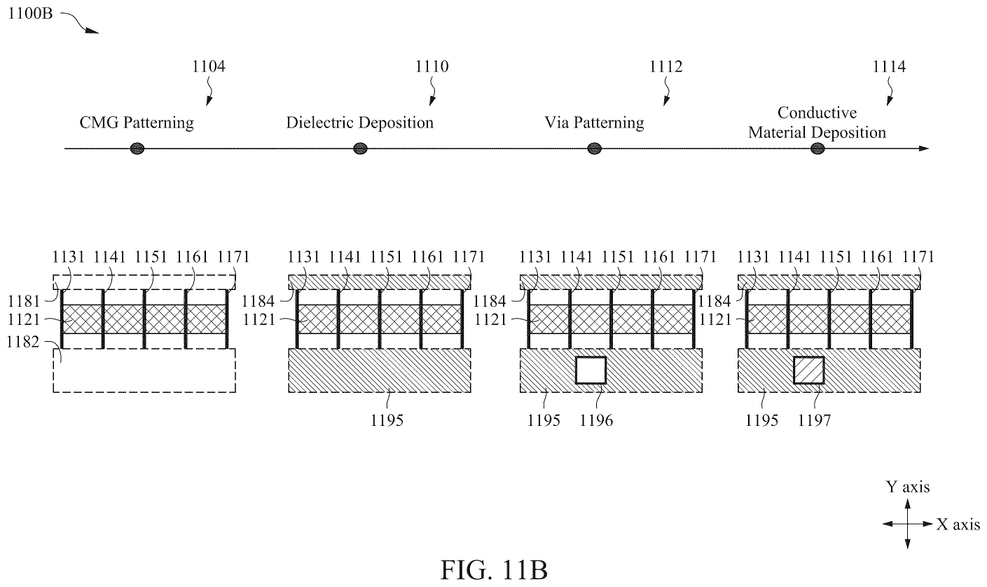

The IC device 300A further comprises a via interconnect 360 embedded in and surrounded by the dielectric structure 350. Along the thickness direction, i.e., the Z axis, the dielectric structure 350 and the via interconnect 360 have a height H1 which is greater than a heigh H of the gate structure of the device stack 308. In at least one embodiment, a top surface (not numbered) of the dielectric structure 350, a top surface 361 of the via interconnect 360, and a top surface (not numbered) of the gate 325 (which is also a top surface of the gate structure of the device stack 308) are flush with each other. In at least one embodiment, a bottom surface (not numbered) of the dielectric structure 350 and a bottom surface 362 of the via interconnect 360 are flush with each other, and are below a bottom surface (not numbered) of the gate 335 (which is also a bottom surface of the gate structure of the device stack 308). The dielectric structure 350 and the via interconnect 360 are co-elevational with the gates 325, 335. In at least one embodiment, the dielectric structure 350 and the via interconnect 360 are co-elevational with an entirety of the gate structure of the device stack 308. The dielectric structure 350 electrically isolates the via interconnect 360 from the gates 325, 335. In some embodiments, the via interconnect 360 is formed using the same CMG mask used to form the dielectric structure 350, and is therefore referred to as a self-aligned via interconnect 360. An example process in accordance with some embodiments is described with respect to FIG. 11A. In at least one embodiment, the via interconnect 360 is formed using a separate mask in addition to the CMG mask used to form the dielectric structure 350. An example process in accordance with some embodiments is described with respect to FIG. 11B.

The via interconnect 360 extends between and electrically couples the MD contact 324 and a back side power rail 391, described in further detail herein. For simplicity, the back side power rail 391 is sometimes referred to as power rail 391. A top portion of the via interconnect 360 is electrically coupled to the MD contact 324. In the example configuration in FIG. 3A, the MD contact 324 extends along the Y axis into the top portion of the via interconnect 360, such that the top surface 361 of the via interconnect 360 is, along the Z axis, between a top surface 326 and a bottom surface 327 of the MD contact 324. Other configurations are within the scopes of various embodiments. For example, in one or more embodiments, the top surface 326 of the MD contact 324 is flush with or below the top surface 361 of the via interconnect 360. A bottom portion of the via interconnect 360 is electrically coupled to the power rail 391. In some embodiments, the via interconnect 360 is in direct contact with the power rail 391. For example, the bottom surface 362 of the via interconnect 360 is over and in direct contact with a top surface of the power rail 391. Other configurations are within the scopes of various embodiments.

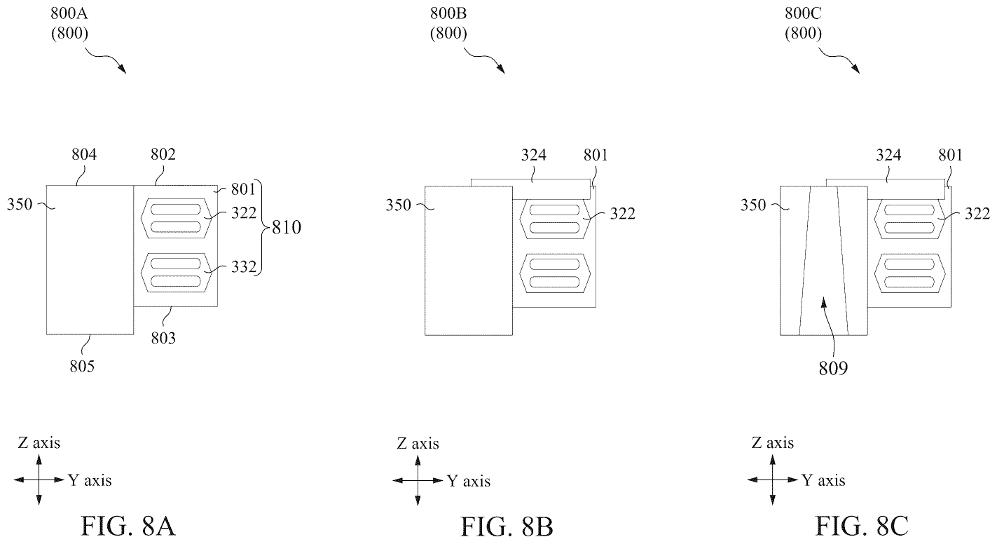

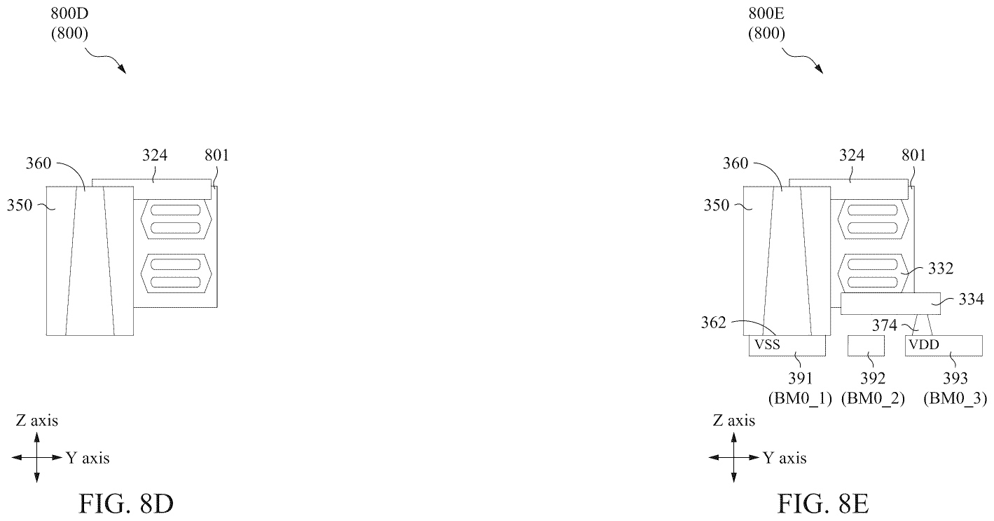

In the example configuration in FIG. 3A, the via interconnect 360 tapers along the thickness direction from the back side power rail 391 towards the MD contact 324. In other words, along the Y axis, a width of the top surface 361 is smaller than a width of the bottom surface 362. In some embodiments, the upwardly tapering shape of the via interconnect 360 is obtained by etching an opening for the via interconnect 360 from the back side of the IC device 300A, as described with respect to FIG. 8C. In some embodiments, the via interconnect 360 and/or the dielectric structure 350 has a center line coinciding, or aligned, with the center line 311. In some embodiments, this arrangement means the via interconnect 360 is shared between a cell (or device stack) on the right side of the center line 311 and another cell (or device stack) on the left side of the center line 311 in FIG. 3A. In the example configuration in FIG. 3A, the MD contact 324 extends along the Y axis towards, but does not reach, the center line 311. This arrangement means, in a plan view along the thickness direction, i.e., the Z axis, the MD contact 324 overlaps less than a half of the via interconnect 360. Other configurations and/or manufacturing methods of the via interconnect 360 are within the scopes of various embodiments.

In some embodiments, the IC device 300A further comprises at least one of a VG via (not shown) over and in electrical contact with the gate 325, or a BVG via (not shown) under and in electrical contact with the gate 335. In at least one embodiment, the IC device 300A further comprises at least one VD via (not shown) over and in electrical contact with the other source/drain of the top semiconductor device MN, or at least one BVD via under and in electrical contact with at least one of the BMD contacts of the bottom semiconductor device MP. In the example configuration in FIG. 3A, the IC device 300A comprises a BVD via 374 under and in electrical contact with the BMD contact 334. Specifically, the BVD via 374 extends from the back side 305, through the substrate 303, to the front side 304 where the BVD via 374 comes into contact with the BMD contact 334.

The IC device 300A further comprises a front side redistribution structure 380, and a back side redistribution structure 390. The redistribution structure 380 is on the front side, over the VD, VG vias, and comprises a plurality of metal layers and via layers sequentially and alternatingly arranged over the VD, VG vias, as described herein with respect to FIG. 1F. The back side redistribution structure 390 is on the back side, and similarly comprises a plurality of metal layers and via layers sequentially and alternatingly arranged under the BVD, BVG vias. A metal layer, i.e., M0 layer, of the front side redistribution structure 380 and a metal layer, i.e., BM0 layer, of the back side redistribution structure 390 are illustrated in FIG. 3A, whereas other layers and/or features of the front side redistribution structure 380 and back side redistribution structure 390 are omitted for simplicity. Among the metal layers of the front side redistribution structure 380, the M0 layer is the metal layer closest to the device stack 308. Among the metal layers of the back side redistribution structure 390, the BM0 layer is the metal layer closest to the device stack 308.

In the example configuration in FIG. 3A, the M0 layer comprises, over the device stack 308, metal patterns 381-384 correspondingly on M0 tracks M0_1-M0_4. In some embodiments, one or more of the metal patterns 381-384 is/are omitted. The tracks M0_1-M0_4 are elongated along the X axis (FIG. 2B), and are arranged side by side along the Y axis. Specifically, the track M0_1 is immediately adjacent to the track M0_2, which is immediately adjacent to the track M0_3, which is immediately adjacent to the track M0_4. Two M0 tracks are considered directly adjacent (or immediately adjacent) where there are no other M0 tracks therebetween. M0 metal patterns on immediately adjacent M0 tracks are considered immediately adjacent. For example, along the Y axis, the metal pattern 381 is immediately adjacent to the metal pattern 382. Along the Y axis, the metal pattern 381 on the track M0_1 has a width greater than a width of each of the metal patterns 382-384 on the tracks M0_2-M0_4.

The metal pattern 381 extends across the center line 311 and is configured to be shared with another device stack (not shown) on the left side of the device stack 308 in FIG. 3A. In some embodiments, the metal pattern 381 has a center line coinciding, or aligned, with the center line 311. In some embodiments, the metal pattern 381 comprises a power rail similar to one or more power rails described with respect to FIG. 2B, but belonging to a front side power delivery network. For example, the metal pattern 381 is configured in one or more embodiments as a VSS power rail to provide VSS to one or more N-type top semiconductor devices in one or more device stacks of the IC device 300A. In at least one embodiment, because power for N-type top semiconductor devices, such as the top semiconductor device MN, is delivered from the back side, e.g., through the via interconnect 360 as described herein, the metal pattern 381 is configured for other purposes, e.g., for signals. For example, in one or more embodiments, a double cell height (2 CH) cell comprises two single cell height (1 CH) structures which are symmetrical across the center line 311, and one of which is the 1 CH structure between the center lines 311, 312 in FIG. 3A. In such a 2 CH cell, the metal pattern 381 is shared between the two 1 CH structures, and is configured as an internal signal pattern of the 2 CH cell.

The metal patterns 382-384 on the tracks M0_2-M0_4 are arranged between the center lines 311, 312. In some embodiments, the metal patterns 382-384 are configured to transmit signals between the device stack 308 and other device stacks or CFET devices in the IC device 300A. The metal patterns 382-384 and the tracks M0_2-M0_4 are sometimes referred correspondingly to as M0 signal patterns and M0 signal tracks. For example, at least one of the metal patterns 382-384 is electrically coupled to the gate 325 or a source/drain of the top semiconductor device MN through a corresponding VG via or VD via. In some embodiments, at least one of the metal patterns 382-384 is electrically coupled to the gate 335 or a source/drain of the bottom semiconductor device MP through a via or local interconnect (not shown) extending between the M0 layer and the gate 335 or the source/drain of the bottom semiconductor device MP. The described number of three M0 signal tracks between the center lines 311, 312 (i.e., over 1 CH) is an example. Other numbers of M0 signal tracks over 1 CH are within the scopes of various embodiments. In at least one embodiment, the M0 layer is free of a power rail directly over the device stack 308, i.e., all of the metal patterns 381-384 are M0 signal patterns.

In the example configuration in FIG. 3A, the BM0 layer comprises, under the device stack 308 and on the back side 305 of the substrate 303, metal patterns 391-393 correspondingly on BM0 tracks BM0_1-BM0_3. The tracks BM0_1-BM0_3 are elongated along the X axis, and are arranged side by side along the Y axis. Specifically, the track BM0_1 is immediately adjacent to the track BM0_2, which is immediately adjacent to the track BM0_3. Two BM0 tracks are considered directly adjacent (or immediately adjacent) where there are no other BM0 tracks therebetween. BM0 metal patterns on immediately adjacent BM0 tracks are considered immediately adjacent. For example, along the Y axis, the metal pattern 391 is immediately adjacent to the metal pattern 392. Along the Y axis, the metal patterns 391, 393 on the tracks BM0_1, BM0_3 has a width greater than a width of the metal pattern 392 on the track BM0_2.

The metal pattern 391 extends across the center line 311 and is configured to be shared with another device stack (not shown) on the left side of the device stack 308 in FIG. 3A. In some embodiments, the metal pattern 391 has a center line coinciding, or aligned, with the center line 311 and/or with the center line of at least one of the dielectric structure 350 or the via interconnect 360. The metal pattern 393 extends across the center line 312 and is configured to be shared with another device stack (not shown) on the right side of the device stack 308 in FIG. 3A. In some embodiments, the metal pattern 393 has a center line coinciding, or aligned, with the center line 312. The metal patterns 391, 393 are configured as back side power rails of a back side power delivery network described with respect to FIG. 2B. In the example configuration in FIG. 3A, the metal pattern 391 is a VSS power rail configured to provide VSS to the top semiconductor device MN and corresponding to one or more of the VSS power rails 220, 222, 224 whereas the metal pattern 393 is a VDD power rail configured to provide VDD to the bottom semiconductor device MP and corresponding to one or more of the VDD power rails 221, 223 in FIG. 2B. The BM0 tracks BM0_1, BM0_3 are sometimes referred to as BM0 power tracks.

The metal pattern 392 on the track BM0_2 is arranged between the center lines 311, 312. In some embodiments, the metal pattern 392 is configured to transmit signals between the device stack 308 and other device stacks, or CFET devices, in the IC device 300A. The metal pattern 392 and the track BM0_2 is sometimes referred correspondingly to as a BM0 signal pattern and a BM0 signal track. For example, the metal pattern 392 is electrically coupled to the gate 335 or a source/drain of the bottom semiconductor device MP through a corresponding BVG via or BVD via. In some embodiments, the metal pattern 392 is electrically coupled to the gate 325 or a source/drain of the top semiconductor device MN through a via or local interconnect (not shown) extending between the BM0 layer and the gate 325 or the source/drain of the top semiconductor device MN. The described number of one BM0 signal track between the center lines 311, 312 (i.e., over 1 CH) is an example. Other numbers of BM0 signal tracks over 1 CH are within the scopes of various embodiments. In some embodiments, the metal pattern 392 and/or the track BM0_2 is/are omitted.

In the example configuration in FIG. 3A, the metal pattern 393, referred to herein as power rail 393, is in electrical contact with the BVD via 374. As a result, VDD on the power rail 393 is provided to the source/drain 332 of the bottom semiconductor device MP through the BVD via 374 and BMD contact 334. In some embodiments, the BVD via 374 is omitted, e.g., when the bottom semiconductor device MP is not directly powered by VDD.

The metal pattern 391, referred to herein as power rail 391, is in electrical contact with the via interconnect 360 which, in turn, is in electrical contact with the MD contact 324. As a result, VSS on the power rail 391 is provided to the source/drain 322 of the top semiconductor device MN through an electrical connection comprising the via interconnect 360 and the MD contact 324. The top semiconductor device MN receives power (i.e., VSS) from the back side power delivery network, rather than from a front side power delivery network. An entirety of the electrical connection from the power rail 391 to the source/drain 322, i.e., the via interconnect 360 and MD contact 324, is below the M0 layer, i.e., below the metal layers of the front side redistribution structure 380. In the example configuration in FIG. 3A, the power rail 391 overlaps, in a plan view along the Z axis, an entirety of at least one of the via interconnect 360 or the metal pattern 381.

As described herein, because the top semiconductor device MN receives power (e.g., VSS) from the back side power delivery network through the via interconnect 360, it is no longer necessary to provide power (e.g., VSS) to the top semiconductor device MN from a front side power delivery network, i.e., from one or more metal layers of the front side redistribution structure 380. In some embodiments, it is possible to configure the IC device 300A to be free of a front side power delivery network. In at least one embodiment, the M0 layer in the IC device 300A is configured to be free of a power rail directly over the via interconnect 360, i.e., the metal pattern 381 is not a power rail. Because a front side power delivery network for powering top semiconductor devices are not required in one or more embodiments, power tap structures for delivery power from the back side power delivery network to a front side power delivery network are also not required. In at least one embodiment, the IC device 300A is free of power tap structures. As a result, it is possible in one or more embodiments to simplify the IC design and/or fabrication, free up front side metal layers for purposes other than power delivery, while saving a chip area that would otherwise be configured as a power tap area for power tap structures.

In some embodiments, one or more circuit regions of the IC device 300A still require a front side power delivery network for design-and/or operation-related reasons. In such embodiments, IC device 300A includes one or more power tap structures. However, the required amount of power tap structures and/or power tap area is still reduced compared to other approaches where top semiconductor devices of CFET devices are powered from a front side power delivery network. Additionally or alternatively, it is possible in one or more embodiments to ensure that a voltage drop (or IR drop) in the power delivery structure for the IC device 300A is within a predetermined or acceptable range. One or more further advantages are achievable in various embodiments, as described herein.

In at least one embodiment, compared to other approaches, the formation of a via interconnect, such as the via interconnect 360, does not increase the number of masks required for an MOL fabrication. For example, other approaches form a vertical local interconnect (VLI) structure for electrical connection from a back side to a front side of an IC device. In an example, such a VLI structure is an in-cell structure, e.g., is confined within the boundary of a cell and/or is not configured to be shared with another cell. In some situations, the formation of a VLI structure requires at least one mask, i.e., a VLI mask and/or a cut-VLI (CVLI) mask. In at least one embodiment, the formation of a VLI structure as in the other approaches is omitted, thereby saving at least one mask. Instead of a VLI structure, a via interconnect, such as the via interconnect 360, is formed in one or more embodiments. As described herein, where the via interconnect is a power via in accordance with some embodiments, an additional mask is required, whereby a same number of masks is used for the MOL fabrication as in the other approaches. However, where the via interconnect is a power wall in accordance with some embodiments, no additional mask is required, whereby the number of masks used for the MOL fabrication is reduced by one mask, compared to the other approaches.

In some embodiments, one or more masks used in an MOL fabrication are EUV masks. In at least one embodiment, EUV masks are reflective masks which are more costly and/or more complex to manufacture than transmissive masks. Therefore, the formation of a via interconnect in accordance with some embodiments, which reduces, or at least does not increase, the number of EUV masks required for an MOL fabrication provides various advantages in terms of manufacturing cost, time, material, complexity, or the like.

In some embodiments, the formation of the via interconnect 360 comprises etching an opening for the via interconnect 360 from the back side of the IC device 300A towards the MD contact 324. The formation of such an opening sometimes involves an MD mis-landing risk, i.e., the etched opening misses, or does not sufficiently expose, the MD contact 324. In at least one embodiment, MD mis-landing risks are greatly reduced or eliminated by reducing the aspect ratio of the opening (or the aspect ratio of the via interconnect 360). In some embodiments, the aspect ratio is reduced by increasing the cross-section area of the opening, or reducing the height (or depth) of the opening. In the example configuration in FIG. 3A, the former is adopted, i.e., the aspect ratio of the opening is reduced by increasing the cross-section area of the opening. In at least one embodiment, by arranging the opening (or the via interconnect 360) on the boundary of a cell or in a space between two immediately adjacent device stacks, it is possible to make the cross-section area of the opening wider than, for example, when the opening is confined within a cell or is formed locally for an individual device stack. As a result, it is possible in one or more embodiments to greatly reduce or eliminate MD mis-landing risks.

The described configuration for power delivery to an N-type top semiconductor device in a device stack is an example. Other configurations are within the scopes of various embodiments. For example, in some embodiments where the device stack 308 comprises a P-type top semiconductor device over an N-type bottom semiconductor device, the power rails 391, 393 are configured correspondingly as a VDD power rail and a VSS power rail, and VDD is provided from the power rail 391 through the electrical connection including the via interconnect 360 to the P-type top semiconductor device. One or more advantages described herein with respect to a device stack, or CFET device, comprising an N-type top semiconductor device over a P-type bottom semiconductor device are also achievable in a device stack, or CFET device, comprising a P-type top semiconductor device over an N-type bottom semiconductor device.

FIG. 3B is a schematic view of a layout 300B of a circuit region of an IC device, in accordance with some embodiments. In some embodiments, the layout 300B corresponds to a circuit region of one or more of IC devices 100, 200A, 300A, and/or a region or a cell of the layout 200B. In at least one embodiment, the layout 300B is stored on a non-transitory computer-readable recording medium. Corresponding components in FIGS. 3A, 3B are designated by the same reference numerals.

In FIG. 3B, the circuit region represented by the layout 300B is a cell that comprises a device stack, or a CFET device, with an NMOS transistor N1 and a PMOS transistor P1. In some embodiments, the transistor N1 and transistor P1 are coupled to configure an inverter and the cell represented by the layout 300B is an inverter cell. In the example configuration in FIG. 3B, the transistor N1 is a top semiconductor device over the transistor P1 which is a bottom semiconductor device.

The layout 300B comprises an upper layer 301 and a lower layer 302. The layout 300B further comprises a boundary 310 (i.e., cell boundary). In some embodiments, the boundary 310 corresponds to the boundary of one or more of the cells C1-C4 described with respect to FIG. 2B. The boundary 310 comprises edges 311, 312, 313, 314. The edges 311, 312 are elongated along the X axis, and the edges 313, 314 are elongated along the Y axis. In some embodiments, the X axis is an example of one of a first direction and a second direction, and the Y axis is an example of the other of the first direction and the second direction. The edges 311, 312, 313, 314 are connected together to form the closed boundary 310. In a place-and-route operation (also referred to as “automated placement and routing (APR)”) described herein, cells are placed in an IC layout in abutment with each other at their respective boundaries. The rectangular shape of the boundary 310 is an example. Other boundary shapes for various cells are within the scope of various embodiments. The cell represented by the layout 300B has a cell height of 1 CH.

The upper layer 301 includes the top semiconductor device, e.g., transistor N1, of the corresponding CFET device. The upper layer 301 comprises an NMOS active region OD_1, and a functional gate region N1 schematically represented by its center line and by the same reference numeral of the corresponding transistor N1 for simplicity. The upper layer 301 further comprises MD contacts MD_0, MD_1, CMG regions CMG_1, CMG_2 of a CMG mask, and a via interconnect PV. In some embodiments, the layout 300B further comprises one or more M0 metal patterns (not shown) along one or more of the tracks M0_1-M0_4. The edges 311, 312 of the boundary 310 correspondingly coincide with the center lines of the regions CMG_1, CMG_2. In some embodiments, the layout 300B further comprises dummy gate regions (not shown) correspondingly on the edges 313, 314 of the boundary 310.

The lower layer 302 includes the bottom semiconductor device, e.g., transistor P1, of the corresponding CFET device. The boundary 310, regions CMG_1, CMG_2, and via interconnect PV are common for both the upper layer 301 and the lower layer 302. The lower layer 302 further comprises a PMOS active region OD_2, and a functional gate region P1 schematically represented by its center line and by the same reference numeral of the corresponding transistor P1 for simplicity. The gate region N1 and the gate region P1 are aligned and share the same center line. The lower layer 302 further comprises BMD contacts BMD_0, BMD_1, a BVD via BVDR, and VSS and VDD power rails (not shown) correspondingly on the tracks BM0_1, BM0_3. In some embodiments, the layout 300B further comprises one or more BM0 metal patterns (not shown) along the track BM0_2.

The described configuration of the layout 300B is an example. In some embodiments, a layout of an IC device comprises, over an active region elongated along the X axis, a plurality of gate regions extending along the Y axis across the active region. The active region and each of the gate regions configure a corresponding CFET device, resulting in a plurality of CFET devices or device stacks. The active region includes both a top active region, e.g., the active region OD_1, for top semiconductor devices of the CFET devices, and a bottom active region, e.g., the active region OD_2, for bottom semiconductor devices of the CFET devices. The gate regions are arranged along the X axis at a regular pitch designated at CPP (contacted poly pitch) as illustrated in FIG. 3B. CPP is a center-to-center distance along the X axis between two directly adjacent gate regions. Two gate regions are considered directly adjacent (or immediately adjacent) where there are no other gate regions therebetween. CFET devices corresponding to immediately adjacent gate regions are considered as immediately adjacent CFET devices. Some gate regions in the layout are functional gate regions which, together with the active region, configure semiconductor devices or transistors coupled into circuitry configured to perform a predetermined operation or function. Examples of functional gate regions are the gate regions N1, P1 described herein. Some other gate regions of the layout are non-functional, or dummy, gate regions. Dummy gate regions are not configured to form transistors together with the active region, and/or one or more transistors formed by dummy gate regions together with the active region are not electrically coupled to other circuitry. In at least one embodiment, non-functional or dummy gates corresponding to dummy gate regions include dielectric material in a manufactured IC device. Examples of dummy gate regions are the gate regions arranged along the edges 313, 314 of the boundary 310.

The length of each of the gate regions is defined or configured by a pair of CMG regions of a CMG mask. For example, the length of each of the gate regions N1, P1 along the Y axis is defined by and between regions CMG_1, CMG_2 which correspond to the dielectric structure 350 and another dielectric structure as described with respect to FIG. 3A. The dielectric structure 350 and a similar dielectric structure described with respect to FIG. 3A are sometimes referred to as gate length defining dielectric structures. in which one or more via interconnects similarly to the via interconnect 360 are embedded.

In some embodiments, each of the regions CMG_1, CMG_2 and the corresponding dielectric structures has a constant width in the Y axis over an entire length of the CMG region or dielectric structure along the X axis. The regions CMG_1, CMG_2 have corresponding center lines 311, 312 spaced from each other along the Y axis by 1 CH. In some embodiments, gate regions in a layout have different lengths. For example, in a region (not shown) where a CMG region is not present, one or more gate regions extend beyond the corresponding center line, e.g., 311 or 312.

In a layout, source/drain contacts, such as MD contacts and BMD contacts, are alternatingly arranged with the gate regions along the X axis. Examples of MD contacts and BMD contacts are contacts MD_0, MD_1, BMD_0, BMD_1. Each MD contact overlies a corresponding BMD contact. For example, the contact MD_0 overlies the contact BMD_0, and the contact MD_1 overlies the contact BMD_1. Two MD contacts (or BMD contacts) are considered directly adjacent (or immediately adjacent) where there are no other MD contacts (or BMD contacts) therebetween along the X axis. A pitch, i.e., a center-to-center distance along the X axis, between directly adjacent MD contacts (or BMD contacts) is the same as the pitch CPP between directly adjacent gate regions. Like the gate regions, the MD contacts and BMD contact are elongated along the Y axis.

In at least one embodiment where the transistor N1 and transistor P1 are coupled to configure an inverter, the gate regions N1, P1 are electrically coupled to each other, e.g., by an MGLI interconnect (not shown). To configure the inverter, the layout 300B further comprises an MDLI interconnect (not shown) which overlaps and electrically couples a source/drain region in the active region OD_1 under the contact MD_1 with a source/drain region in the active region OD_2 over the contact BMD_1.

In at least one embodiment, as described herein, the cross-sectional view in FIG. 3A is a combination of two cross-sectional views, i.e., one view along a cross-section A-A′ along the center line of the gate region G1, and another view along a cross-section B-B′ along the center line of the contacts MD_0, BMD_0 in FIG. 3B. For example, a source/drain in the active region OD_1 under the contact MD_0 corresponds to the source/drain 322, and a source/drain in the active region OD_2 over the contact BMD_0 corresponds to the source/drain 332. The gate region N1 corresponds to the gate 325, and the gate region P1 corresponds to the gate 335. The contact MD_0 corresponds to the MD contact 324, and the contact BMD_0 corresponds to the BMD contact 334. The region CMG_1 corresponds to the dielectric structure 350, and the via interconnect PV corresponds to the via interconnect 360. The via BVDR corresponds to the BVD via 374.

In FIG. 3B, the VDD power rail on the track BM0_3 is elongated along the X axis and overlaps the via BVDR and the contact BMD_0, whereas the contact BMD_0 overlaps a source/drain of the transistor P1 in the active region OD_2. As a result, the VDD power rail on the track BM0_3 is electrically coupled to the source/drain of the transistor P1 by the via BVDR and contact BMD_0. The VSS power rail on the track BM0_1 is elongated along the X axis and overlaps the via interconnect PV and the contact MD_0, whereas the contact MD_0 overlaps a source/drain of the transistor N1 in the active region OD_1. As a result, the VSS power rail on the track BM0_1 is electrically coupled to the source/drain of the transistor N1 by the via interconnect PV and contact MD_0. Thus, power is provided from the back side power delivery network to the top semiconductor device N1, through the via interconnect PV, in a manner as described herein. In some embodiments, the VSS power rail on the track BM0_1 overlaps an entirety of the via interconnect PV. One or more advantages described herein are achievable by the layout 300B and/or by a manufactured IC device corresponding to the layout 300B, in accordance with some embodiments.

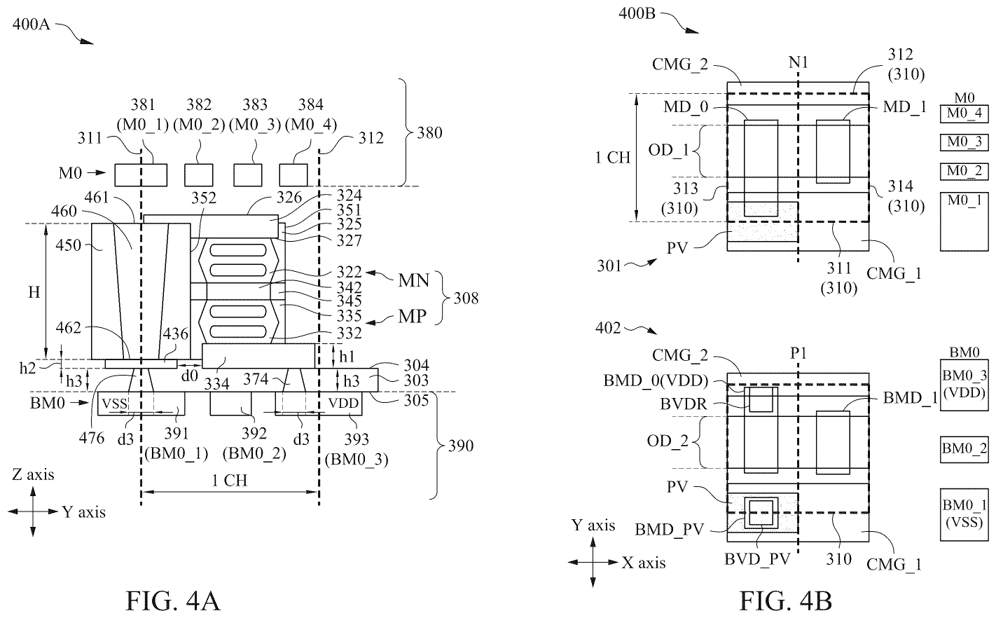

FIG. 4A is a schematic cross-sectional view of a circuit region of an IC device 400A, in accordance with some embodiments. In some embodiments, the IC device 400A corresponds to one or more of the IC devices 100, 200A, 300A and the layouts 200B, 300B. The cross-sectional view in FIG. 4A is similar to the cross-sectional view in FIG. 3A, and corresponding components in FIGS. 3A, 4A are designated by the same reference numerals. The IC device 400A differs from the IC device 300A in the configuration of a via interconnect and how the via interconnect is electrically coupled to a back side power rail.

The IC device 400A comprises a dielectric structure 450 corresponding to the dielectric structure 350, and in contact with the gates 325, 335 along the surface 352. In some embodiments, the dielectric structure 450 corresponds to a CMG region of a CMG mask configured to define or configure the length of the gates 325, 335. Like the IC device 300A, the IC device 400A comprises a further dielectric structure (not shown for simplicity) similar to the dielectric structure 450, but on the other side of the gates 325, 335 along the Y axis, and in contact with the gates 325, 335 along the surface 351 opposite to the surface 352. The length of the gates 325, 335 is defined or configured by a distance along the Y axis between the dielectric structure 450 and the further dielectric structure. In the example configuration in FIG. 4A, the dielectric structure 450 and the further dielectric structure have corresponding center lines 311, 312.

The IC device 400A further comprises a via interconnect 460 corresponding to the via interconnect 360. The via interconnect 460 is embedded in and surrounded by the dielectric structure 450. The dielectric structure 450 electrically isolates the via interconnect 460 from the gates 325, 335. In at least one embodiment, a top surface (not numbered) of the dielectric structure 450, a top surface 461 of the via interconnect 460, and a top surface (not numbered) of the gate 325 (which is also a top surface of the gate structure of the device stack 308) are flush with each other. In at least one embodiment, a bottom surface (not numbered) of the dielectric structure 450 and a bottom surface 462 of the via interconnect 460 are flush with each other, and with a bottom surface (not numbered) of the gate 335 (which is also a bottom surface of the gate structure of the device stack 308).

Compared to the dielectric structure 350 and via interconnect 360, the dielectric structure 450 and the via interconnect 460 have a lower height. In the example configuration in FIG. 4A, along the thickness direction, i.e., the Z axis, the dielectric structure 450 and the via interconnect 460 have the same height H as the gate structure of the device stack 308 which is smaller than the height H1 of the dielectric structure 350 and via interconnect 360. In at least one embodiment, an entirety of the gate 325 and/or an entirety of the gate 335 is/are co-elevational with the dielectric structure 450 and/or the via interconnect 460.

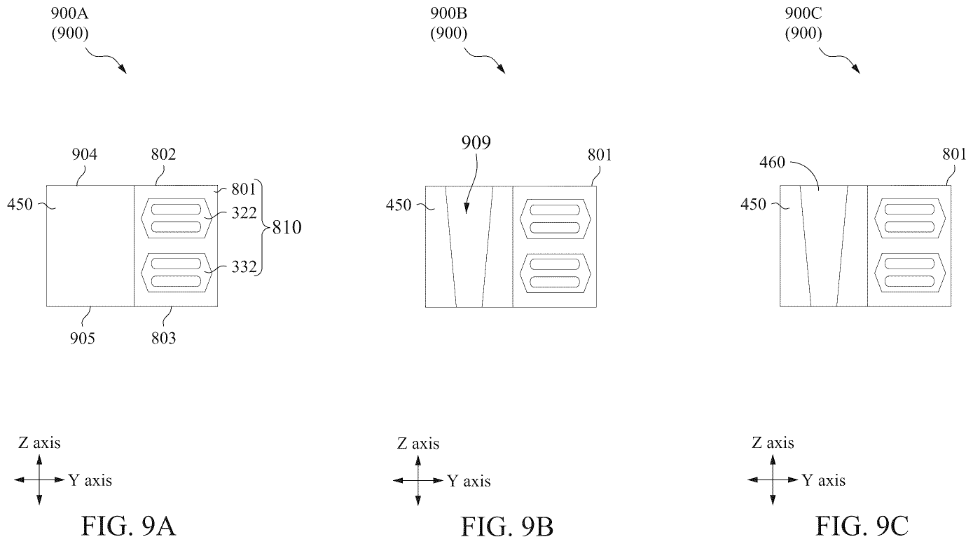

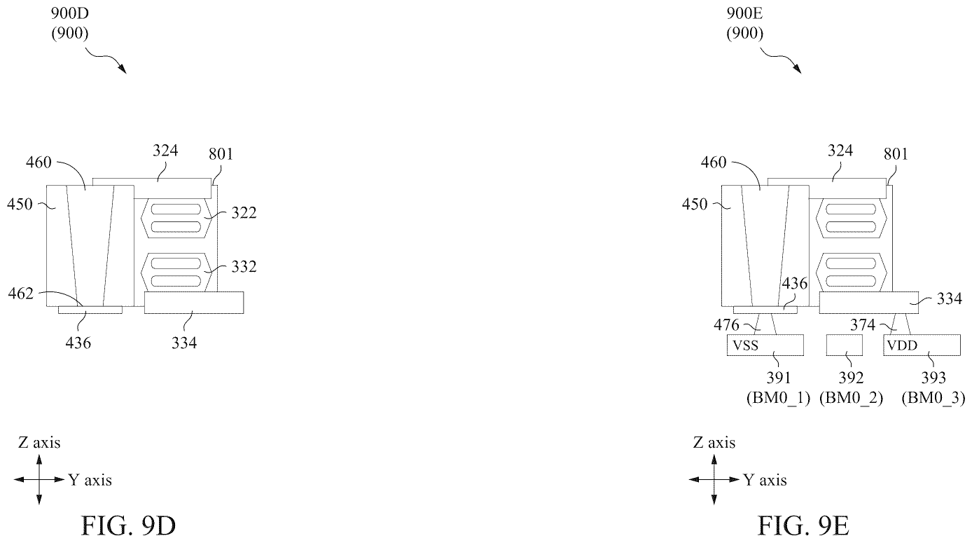

Further, compared to the via interconnect 360 which tapers along the Z axis from the back side power rail 391 towards the MD contact 324, the via interconnect 460 tapers along the Z axis in the opposite direction, from the MD contact 324 towards the back side power rail 391. In other words, along the Y axis, a width of the top surface 461 of the via interconnect 460 is greater than a width of the bottom surface 462 of the via interconnect 460. In some embodiments, the downwardly tapering shape of the via interconnect 460 is obtained by etching an opening for the via interconnect 460 from the front side of the IC device 400A, as described with respect to FIG. 9B. In some embodiments, the via interconnect 460 and/or the dielectric structure 450 has a center line coinciding, or aligned, with the center line 311. In some embodiments, this arrangement means the via interconnect 460 is shared between a cell (or device stack) on the right side of the center line 311 and another cell (or device stack) on the left side of the center line 311 in FIG. 4A. In the example configuration in FIG. 4A, the MD contact 324 extends along the Y axis towards, but does not reach, the center line 311. This arrangement means, in a plan view along the thickness direction, i.e., the Z axis, the MD contact 324 overlaps less than a half of the via interconnect 460. Other configurations and/or manufacturing methods of the via interconnect 460 are within the scopes of various embodiments.

The IC device 400A further comprises a conductor 436 co-elevational with the BMD contact 334 along the Z axis, and spaced from the BMD contact 334 along the Y axis by a spacing d0. In some embodiments, a first element is co-elevational with a second element when at least one portion of the first element and at least one portion of the second element are in a plane perpendicular to the Z axis. In at least one embodiment, an entirety of the conductor 436 is co-elevational with the BMD contact 334. In some embodiments, the conductor 436 comprises the same material as the BMD contact 334. In some embodiments, the conductor 436 is formed simultaneously with the BMD contact 334, from the same material, in the same manufacturing process, using the same mask, e.g., a BMD mask which is an EUV mask in one or more embodiments. In other words, the conductor 436 is a bottom contact structure like the BMD contact 334, with the exception that the conductor 436 does not overlap and is not in contact with a source/drain or an active region. Further, along the Z axis, a height h1 of the BMD contact 334 is greater than a height h2 of the conductor 436. In other words, the conductor 436 is thinner than the BMD contact 334. In some embodiments, a bottom surface (not numbered) of the conductor 436 is flush with a bottom surface (not numbered) of the BMD contact 334. In at least one embodiment, the spacing d0 between the BMD contact 334 and the conductor 436 along the Y axis is equal to or greater than a predetermined spacing, for ensuring that the IC device 400A is manufacturable.

A top portion of the via interconnect 460 is electrically coupled to the MD contact 324. In the example configuration in FIG. 4A, the MD contact 324 extends along the Y axis into the top portion of the via interconnect 460, such that the top surface 461 of the via interconnect 460 is, along the Z axis, between the top surface 326 and the bottom surface 327 of the MD contact 324. Other configurations are within the scopes of various embodiments. A bottom portion of the via interconnect 460 is electrically coupled to the conductor 436. In the example configuration in FIG. 4A, the bottom surface 462 of the via interconnect 460 is over and in contact with a top surface of the conductor 436. Other configurations are within the scopes of various embodiments.

The IC device 400A further comprises a via 476 under and in electrical contact with the conductor 436. Specifically, the via 476 extends from the back side 305, through the substrate 303, to the front side 304 where the via 476 comes into contact with the conductor 436. In some embodiments, the via 476 comprises the same material as the BVD via 374. In some embodiments, the via 476 is formed simultaneously with the BVD via 374, from the same material, in the same manufacturing process, using the same mask, e.g., a BVD mask. In other words, the via 476 is a BVD via like the BVD via 374, with the exception that the via 476 is in contact with the conductor 436 rather than with a BMD contact on a source/drain or an active region. In some embodiments, a height h3 of the BVD via 476 is the same as a height h3 of the BVD via 374, and/or a greatest dimension d3 of the BVD via 476 in an X-Y plane is the same as the greatest dimension d3 of the BVD via 374 in the X-Y plane.

The power rail 391 is in electrical contact with the BVD via 476, and is electrically coupled to the via interconnect 460 through the BVD via 476 and the conductor 436. As a result, VSS on the power rail 391 is provided to the source/drain 322 of the top semiconductor device MN through an electrical connection comprising the BVD via 476, conductor 436, via interconnect 460, and MD contact 324. The top semiconductor device MN receives power (i.e., VSS) from the back side power delivery network, rather than from a front side power delivery network. An entirety of the electrical connection from the power rail 391 to the source/drain 322, i.e., the BVD via 476, conductor 436, via interconnect 460 and MD contact 324, is below the M0 layer, i.e., below the metal layers of the front side redistribution structure 380. In the example configuration in FIG. 4A, the power rail 391 overlaps, along the Z axis, an entirety of at least one of the BVD via 476, the conductor 436, the via interconnect 460, or the metal pattern 381.

In at least one embodiment, compared to other approaches, the formation of a via interconnect, such as the via interconnect 460, and corresponding features, such as the conductor 436 and BVD via 476, does not increase the number of masks required for an MOL fabrication. A reason is that the conductor 436 is manufacturable by using a same mask as BMD contacts, whereas the BVD via 476 is manufacturable by using a same mask as other BVD vias. Further, in at least one embodiment, the formation of a VLI structure as in the other approaches is omitted, thereby saving at least one mask. Instead of a VLI structure, a via interconnect, such as the via interconnect 460, is formed in one or more embodiments. As described herein, when the via interconnect is a power via, a same number of masks is used for the MOL fabrication as in the other approaches, whereas when the via interconnect is a power wall, the number of masks used for the MOL fabrication is reduced by one mask, compared to the other approaches. One or more advantages described herein are achievable by the IC device 400A, in accordance with some embodiments.

FIG. 4B is a schematic view of a layout 400B of a circuit region of an IC device, in accordance with some embodiments. In some embodiments, the layout 400B corresponds to a circuit region of one or more of IC devices 100, 200A, 300A, 400A and/or a region or a cell of the layouts 200B, 300B. In at least one embodiment, the layout 400B is stored on a non-transitory computer-readable recording medium. The layout in FIG. 4B is similar to the layout in FIG. 3B, and corresponding components in FIGS. 3B, 4B are designated by the same reference numerals. The layout 400B differs from the layout 300B in the lower layer which additionally includes features for electrically coupling a back side power rail to a via interconnect.

The layout 400B comprises the upper layer 301 as in the layout 300B, and a lower layer 402. Compared to the lower layer 302 of the layout 300B, the lower layer 402 additionally comprises a contact BMD_PV and a via BVD_PV. In some embodiments, the contact BMD_PV belongs to the same mask as other BMD contacts, such as the contacts BMD_0, BMD_1, and/or the via BVD_PV belongs to the same mask as other BVD vias, such as the via BVDR. As can be seen in FIG. 4B, the contact BMD_0 is spaced, along the Y axis, from the contact BMD_PV by a distance corresponding to the spacing d0. In some embodiments, in the layout in FIG. 4B, the via BVDR has the same size as the via BVD_PV. In at least one embodiment, the region CMG_1 corresponds to the dielectric structure 450, the via interconnect PV corresponds to the via interconnect 460, the via BVD_PV corresponds to the BVD via 476, and the contact BMD_PV corresponds to the conductor 436.

The VSS power rail on the track BM0_1 is elongated along the X axis and overlaps the via BVD_PV, the contact BMD_PV, the via interconnect PV and the contact MD_0. As a result, the VSS power rail on the track BM0_1 is electrically coupled to the source/drain of the transistor N1 by the via BVD_PV, the contact BMD_PV, the via interconnect PV and the contact MD_0. Thus, power is provided from the back side power delivery network to the top semiconductor device N1, through the via interconnect PV, in a manner as described herein. In some embodiments, the VSS power rail on the track BM0_1 overlaps an entirety of at least one of the via BVD_PV, contact BMD_PV, or the via interconnect PV. One or more advantages described herein are achievable by the layout 400B and/or by a manufactured IC device corresponding to the layout 400B, in accordance with some embodiments.

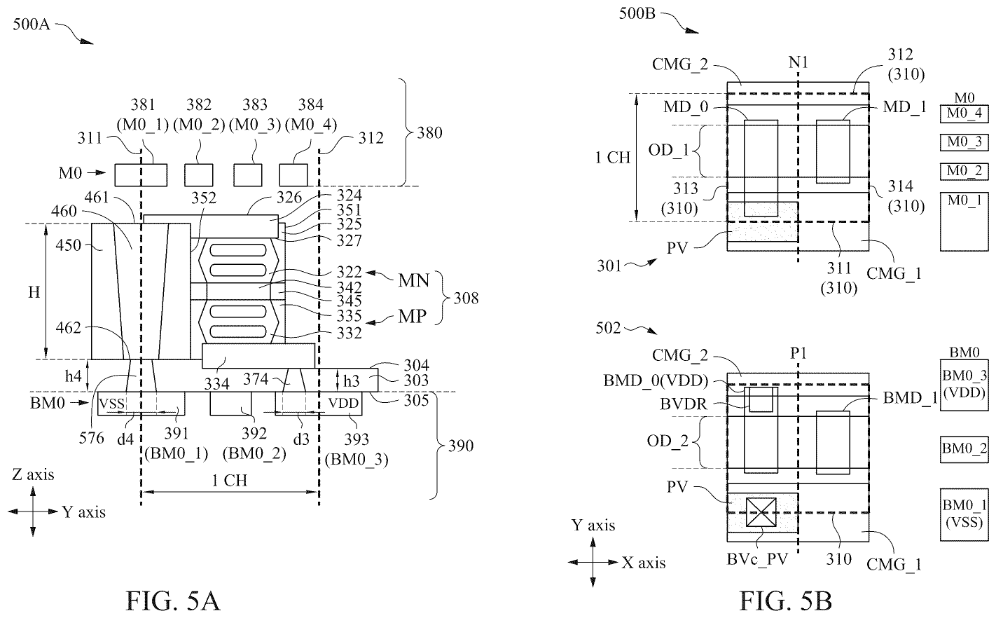

FIG. 5A is a schematic cross-sectional view of a circuit region of an IC device 500A, in accordance with some embodiments. In some embodiments, the IC device 500A corresponds to one or more of the IC devices 100, 200A, 300A, 400A and the layouts 200B, 300B, 400B. The cross-sectional view in FIG. 5A is similar to the cross-sectional view in FIG. 4A, and corresponding components in FIGS. 4A, 5A are designated by the same reference numerals. The IC device 500A differs from the IC device 400A in how a via interconnect is electrically coupled to a back side power rail.

Compared to the IC device 400A, the IC device 500A comprises a back side via 576 instead of the conductor 436 and BVD via 476 of the IC device 400A. The back side via 576 extends from the back side 305, through the substrate 303, to the front side 304 where the back side via 576 comes into contact with the via interconnect 460. The back side via 576 has top surface in electrical contact with the bottom surface 462 of the via interconnect 460, and a bottom surface in electrical contact with the power rail 391. In some embodiments, at least one of the electrical contact between the back side via 576 and the via interconnect 460 or the electrical contact between the back side via 576 and the power rail 391 is a directed contact. The back side via 576 has an upper portion co-elevational with a lower portion of the BMD contact 334 along the Z axis, and a lower portion co-elevational with the BVD via 374. In at least one embodiment, an entirety of the BVD via 374 is co-elevational with the back side via 576. A height h4 of the back side via 576 is greater than the height h3 of the BVD via 374. In at least one embodiment, a greatest dimension d4 of the back side via 576 in the X-Y plane is larger than the greatest dimension d3 of the BVD via 374 in the X-Y plane. In some embodiments, the back side via 576 comprises the same material as the BVD via 374 and/or other BVD vias.

The power rail 391 is in electrical contact with the back side via 576, and is electrically coupled to the via interconnect 460 through the back side via 576. As a result, VSS on the power rail 391 is provided to the source/drain 322 of the top semiconductor device MN through an electrical connection comprising the back side via 576, via interconnect 460, and MD contact 324. The top semiconductor device MN receives power (i.e., VSS) from the back side power delivery network, rather than from a front side power delivery network. An entirety of the electrical connection from the power rail 391 to the source/drain 322, i.e., the back side via 576, via interconnect 460 and MD contact 324, is below the M0 layer, i.e., below the metal layers of the front side redistribution structure 380. In the example configuration in FIG. 4A, the power rail 391 overlaps, along the Z axis, an entirety of at least one of the back side via 576, the via interconnect 460, or the metal pattern 381.

In at least one embodiment, the back side via 576 is formed in a separate process using a separate mask from the process and the BVD mask for forming BVD vias, such as the BVD via 374. A reason is because the back side via 576 has a different size and/or height from BVD vias. In at least one embodiment, the formation of a VLI structure as in the other approaches is omitted, thereby saving at least one mask. Instead of a VLI structure, a via interconnect, such as the via interconnect 460, is formed in one or more embodiments. When the via interconnect is a power via in accordance with some embodiments, the formation of a via interconnect, such as the via interconnect 460, and a corresponding feature, such as the back side via 576, increases the number of masks required for an MOL fabrication by one mask, i.e., the separate mask for manufacturing the back side via 576 or the like. When the via interconnect is a power wall in accordance with some embodiments, a same number of masks is used for the MOL fabrication as in the other approaches, despite the separate mask for manufacturing the back side via 576 or the like. One or more advantages described herein are achievable by the IC device 500A, in accordance with some embodiments.

FIG. 5B is a schematic view of a layout 500B of a circuit region of an IC device, in accordance with some embodiments. In some embodiments, the layout 500B corresponds to a circuit region of one or more of IC devices 100, 200A, 300A, 400A, 500A and/or a region or a cell of the layouts 200B, 300B, 400B. In at least one embodiment, the layout 500B is stored on a non-transitory computer-readable recording medium. The layout in FIG. 5B is similar to the layout in FIGS. 3B, 4B, and corresponding components in FIGS. 3B, 4B, 5B are designated by the same reference numerals. The layout 500B differs from the layouts 300B, 400B in the lower layer which includes a different feature for electrically coupling a back side power rail to a via interconnect.

The layout 500B comprises the upper layer 301 as in the layout 300B, and a lower layer 502. Compared to the lower layer 302 of the layout 300B, the lower layer 402 additionally comprises a back side via BVc_PV. In some embodiments, the via BVc_PV belongs to, or is manufactured by, a separate mask from the mask for forming BVD vias, such as the via BVDR. In some embodiments, the separate mask for forming the via BVc_PV is a EUV mask. In the example configuration in FIG. 5B, a size of the via BVc_PV is greater than that of the via BVDR. For example, a width of the via BVc_PV along the X axis is greater than that of the via BVDR, and a height of the via BVc_PV along the Y axis is also greater than that of the via BVDR. In at least one embodiment, the region CMG_1 corresponds to the dielectric structure 450, the via interconnect PV corresponds to the via interconnect 460, and the via BVc_PV corresponds to the back side via 576.

The VSS power rail on the track BM0_1 is elongated along the X axis and overlaps the via BVc_PV, the via interconnect PV and the contact MD_0. As a result, the VSS power rail on the track BM0_1 is electrically coupled to the source/drain of the transistor N1 by the via BVc_PV, the via interconnect PV and the contact MD_0. Thus, power is provided from the back side power delivery network to the top semiconductor device N1, through the via interconnect PV, in a manner as described herein. In some embodiments, the VSS power rail on the track BM0_1 overlaps an entirety of at least one of the via BVc_PV or the via interconnect PV. One or more advantages described herein are achievable by the layout 500B and/or by a manufactured IC device corresponding to the layout 500B, in accordance with some embodiments.

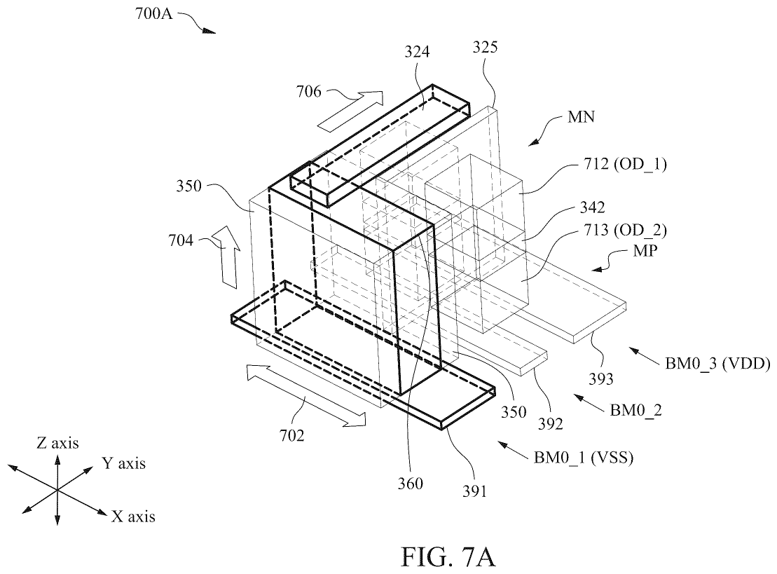

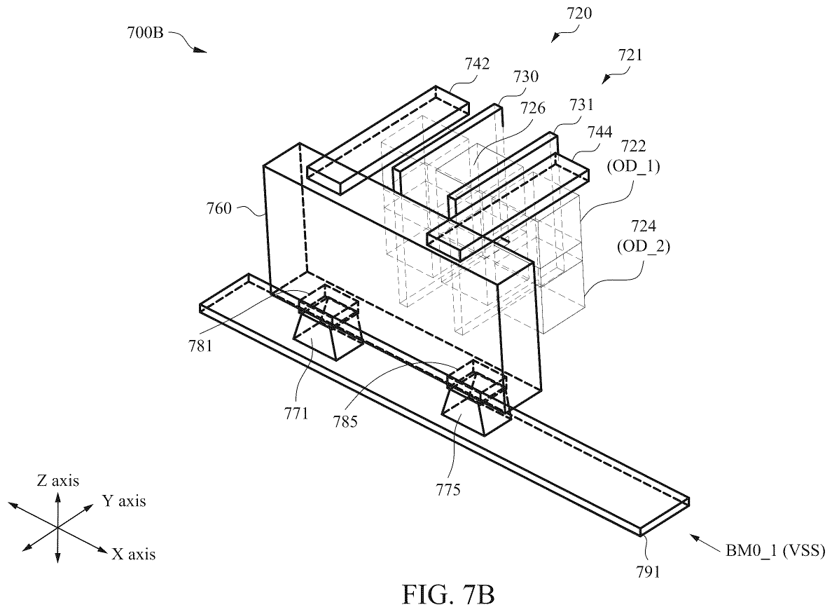

The via interconnect PV described with respect to FIGS. 3B, 4B, 5B is an example of a power via. A further example of a power via is described with respect to FIG. 7A. In some embodiments, a power via is configured for power delivery for a single cell or a single CFET device, e.g., as described with respect to FIGS. 3B, 4B, 5B. In at least one embodiment, a power via is formed by using a mask different or separate from a CMG mask used for forming a dielectric structure in which the power via is embedded.

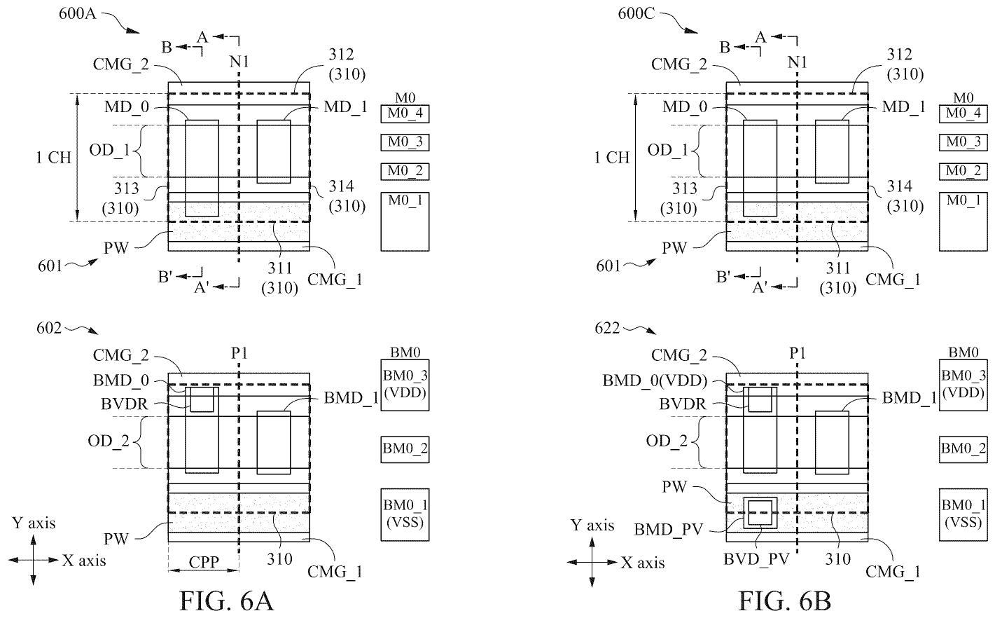

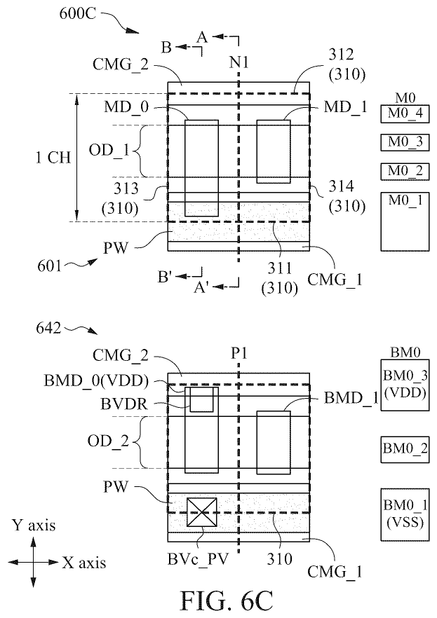

A further configuration of a via interconnect comprises a power wall. Various examples of power walls are described with respect to FIGS. 6A, 6B, 6C, 7B. In some embodiments, a power wall is configured for power delivery for several cells or several CFET devices. In at least one embodiment, a power wall is formed by using the same CMG mask used for forming a dielectric structure in which the power wall is embedded.

FIG. 6A is a schematic view of a layout 600A of a circuit region of an IC device, in accordance with some embodiments. In some embodiments, the layout 600A corresponds to a circuit region of one or more of IC devices 100, 200A, 300A, 400A, 500A and/or a region or a cell of the layouts 200B, 300B, 400B, 500B. In at least one embodiment, the layout 600A is stored on a non-transitory computer-readable recording medium. The layout in FIG. 6A is similar to the layout in FIGS. 3B, 4B, 5B and corresponding components in FIGS. 3B, 4B, 5B, 6A are designated by the same reference numerals. The layout 600A differs from the layout 300B in the configuration of a via interconnect, i.e., the layout 600A comprises a power wall instead of a power via as in the layout 300B.

The layout 600A comprises an upper layer 601 and a lower layer 602. The upper layer 601 is the same as the upper layer 301 of the layout 300B, except that the upper layer 601 comprises a via interconnect PW, which is a power wall, instead of the via interconnect PV, which is a power via, of the layout 300B. Likewise, the lower layer 602 is the same as the lower layer 302 of the layout 300B, except for the via interconnect PW replacing the via interconnect PV of the layout 300B. The cross-sectional view in FIG. 3A corresponds to a combination of two cross-sectional views taken in FIG. 6A, i.e., one view along the cross-section A-A′ along the center line of the gate region G1, and another view along the cross-section B-B′ along the center line of the contacts MD_0, BMD_0 in FIG. 6A. A VSS power rail (not shown) on the track BM0_1 is elongated along the X axis and overlaps the via interconnect PW and the contact MD_0, whereas the contact MD_0 overlaps a source/drain of the transistor N1 in the active region OD_1. As a result, the VSS power rail on the track BM0_1 is electrically coupled to the source/drain of the transistor N1 by the via interconnect PW and contact MD_0. Thus, power is provided from the back side power delivery network to the top semiconductor device N1, through the via interconnect PV, in a manner as described herein. In some embodiments, the VSS power rail on the track BM0_1 overlaps an entirety of the via interconnect PW.

In FIG. 3B, the via interconnect PV is a power via for a single cell within the boundary 310 or for a single CFET device comprising the transistors N1, P1. The via interconnect PV has a limited dimension along the X axis which is independent from a dimension of the corresponding region CMG_1 along the X axis. For example, the via interconnect PV does not overlap the contacts MD_1, BMD_1 along the Y axis. The limited or independent dimension of the via interconnect PV along the X axis is a reason, in one or more embodiments, the via interconnect PV belongs to a separate mask from the CMG mask containing the region CMG_1. The via interconnect PV belonging to such a separate mask is sometimes referred to as a non-self-aligned feature. In some embodiments, the separate mask for forming the via interconnect PV is a EUV mask.

In FIG. 6A, the via interconnect PW is a power wall for several cells or for several CFET devices. The via interconnect PW is longer than the via interconnect PV, and overlaps the contacts MD_1, BMD_1 along the Y axis. Although the via interconnect PW is illustrated in FIG. 6A to extend up to the edges 313, 314, the via interconnect PW actually extends along the X axis beyond at least one of the edges 313, 314 to provide power delivery to one or more cells and/or CFET devices outside the boundary 310. In some embodiments, a dimension of the via interconnect PW along the X axis corresponds to the dimension of the region CMG_1 along the X axis. In some embodiments, a via interconnect (e.g., the via interconnect 360) corresponding to the via interconnect PW is manufactured by the same CMG mask containing the region CMG_1. As a result, the via interconnect PW is sometimes referred to as a self-aligned feature.

Compared to the via interconnect PV, the via interconnect PW is physically longer and potentially causes more parasitic capacitance than the via interconnect PV. However, the formation of the via interconnect PW, in one or more embodiments, does not require a separate mask (e.g., a EUV mask) from the CMG mask. As a result, manufacturing cost, time and/or material is/are reduced compared to embodiments where the via interconnect PV is used for power delivery. In some embodiments, a tradeoff between lower parasitic capacitance (with the via interconnect PV) and lower manufacturing cost, time and/or material (with the via interconnect PW) is a consideration during the IC device design and/or fabrication stages. One or more advantages described herein are achievable by the layout 600A and/or by a manufactured IC device corresponding to the layout 600A, in accordance with some embodiments.

FIG. 6B is a schematic view of a layout 600B of a circuit region of an IC device, in accordance with some embodiments. In some embodiments, the layout 600B corresponds to a circuit region of one or more of IC devices 100, 200A, 300A, 400A, 500A and/or a region or a cell of the layouts 200B, 300B, 400B, 500B, 600A. In at least one embodiment, the layout 600B is stored on a non-transitory computer-readable recording medium. The layout in FIG. 6B is similar to the layout in FIGS. 3B, 4B, 5B, 6A and corresponding components in FIGS. 3B, 4B, 5B, 6A, 6B are designated by the same reference numerals. The layout 600B differs from the layout 400B in the configuration of a via interconnect, i.e., the layout 600B comprises a power wall instead of a power via as in the layout 400B.

The layout 600B comprises the upper layer 601 and a lower layer 622. The lower layer 622 is the same as the lower layer 402 of the layout 400B, except for the via interconnect PW replacing the via interconnect PV of the layout 400B. The cross-sectional view in FIG. 4A corresponds to a combination of two cross-sectional views taken in FIG. 6B, i.e., one view along the cross-section A-A′ along the center line of the gate region G1, and another view along the cross-section B-B′ along the center line of the contacts MD_0, BMD_0 in FIG. 6B.

A VSS power rail (not shown) on the track BM0_1 is elongated along the X axis and overlaps the via BVD_PV, the contact BMD_PV, the via interconnect PW and the contact MD_0. As a result, the VSS power rail on the track BM0_1 is electrically coupled to the source/drain of the transistor N1 by the via BVD_PV, the contact BMD_PV, the via interconnect PW and the contact MD_0. Thus, power is provided from the back side power delivery network to the top semiconductor device N1, through the via interconnect PW, in a manner as described herein. In some embodiments, the VSS power rail on the track BM0_1 overlaps an entirety of at least one of the via BVD_PV, contact BMD_PV, or the via interconnect PW. One or more advantages described herein are achievable by the layout 600B and/or by a manufactured IC device corresponding to the layout 600B, in accordance with some embodiments.

FIG. 6C is a schematic view of a layout 600C of a circuit region of an IC device, in accordance with some embodiments. In some embodiments, the layout 600C corresponds to a circuit region of one or more of IC devices 100, 200A, 300A, 400A, 500A and/or a region or a cell of the layouts 200B, 300B, 400B, 500B, 600A, 600B. In at least one embodiment, the layout 600C is stored on a non-transitory computer-readable recording medium. The layout in FIG. 6C is similar to the layout in FIGS. 3B, 4B, 5B, 6A, 6B and corresponding components in FIGS. 3B, 4B, 5B, 6A, 6B, 6C are designated by the same reference numerals. The layout 600C differs from the layout 500B in the configuration of a via interconnect, i.e., the layout 600C comprises a power wall instead of a power via as in the layout 500B.

The layout 600C comprises the upper layer 601 and a lower layer 642. The lower layer 642 is the same as the lower layer 502 of the layout 500B, except for the via interconnect PW replacing the via interconnect PV of the layout 500B. The cross-sectional view in FIG. 5A corresponds to a combination of two cross-sectional views taken in FIG. 6C, i.e., one view along the cross-section A-A′ along the center line of the gate region G1, and another view along the cross-section B-B′ along the center line of the contacts MD_0, BMD_0 in FIG. 6C.

A VSS power rail (not shown) on the track BM0_1 is elongated along the X axis and overlaps the via BVc_PV, the via interconnect PW and the contact MD_0. As a result, the VSS power rail on the track BM0_1 is electrically coupled to the source/drain of the transistor N1 by the via BVc_PV, the via interconnect PW and the contact MD_0. Thus, power is provided from the back side power delivery network to the top semiconductor device N1, through the via interconnect PW, in a manner as described herein. In some embodiments, the VSS power rail on the track BM0_1 overlaps an entirety of at least one of the via BVc_PV or the via interconnect PW. One or more advantages described herein are achievable by the layout 600C and/or by a manufactured IC device corresponding to the layout 600C, in accordance with some embodiments.

FIG. 7A is a schematic perspective view of a circuit region of an IC device 700A, in accordance with some embodiments. In some embodiments, the IC device 700A corresponds to one or more of IC devices 100, 200A, 300A and/or the layouts 200B, 300B. Corresponding components in FIGS. 3A, 3B, 7A are designated by the same reference numerals. In some embodiments, the perspective view in FIG. 7A corresponds to the cross-sectional view in FIG. 3A and the layout in FIG. 3B, and shows a power via in the form of the via interconnect 360.

In FIG. 7A, the other source/drains of the top semiconductor device MN and bottom semiconductor device MP, which are not visible in FIG. 3A, are shown. Specifically, the top semiconductor device MN comprises a source/drain 712 which, together with the source/drain 322 (below the MD contact 324 in FIG. 7A) and the channel 321 (not shown in FIG. 7A), belongs to a top active region OD_1. The bottom semiconductor device MP comprises a source/drain 713 which, together with the source/drain 332 (not shown in FIG. 7A) and the channel 331 (not shown in FIG. 7A), belongs to a bottom active region OD_2. The power rail 391 is in electrical contact with the via interconnect 360 which, in turn, is in electrical contact with the MD contact 324. FIG. 7A includes arrows 702, 704, 706 schematically showing a connection along which VSS is delivered from the power rail 391, through the via interconnect 360 and the MD contact 324 to the source/drain 322 (not shown in FIG. 7A).

In some embodiments, the IC device 700A comprises a conductor and a BVD via (not shown) between the power rail 391 and the via interconnect 360 in a configuration similar to that described with respect to FIG. 7B and corresponding to the cross-sectional view in FIG. 4A. In some embodiments, the IC device 700A comprises a back side via (not shown) between the power rail 391 and the via interconnect 360 in a configuration corresponding to the cross-sectional view in FIG. 5A. One or more advantages described herein are achievable by the IC device 700A, in accordance with some embodiments.

FIG. 7B is a schematic perspective view of a circuit region of an IC device 700B, in accordance with some embodiments. In some embodiments, the IC device 700B corresponds to one or more of IC devices 100, 200A, 400A and/or the layouts 200B, 600B. In some embodiments, the perspective view in FIG. 7B corresponds to the cross-sectional view in FIG. 4A and the layout in FIG. 6B, and shows a power wall in the form of a via interconnect 760.

The IC device 700B comprises a plurality of CFET devices 720, 721 arranged along the X axis. In some embodiments, each of the CFET devices 720, 721 corresponds to the device stack 100A. The CFET devices 720, 721 comprise corresponding gates 730, 731 extending along the Y axis across an active region which comprises a top active region OD_1 and a bottom active region OD_2. The CFET devices 720, 721 and the corresponding gates 730, 731 are immediately adjacent along the X axis. Areas of the active region on opposite sides of a gate region form source/drains of the corresponding CFET device. The IC device 700B comprises an MD contact 742 over and in electrical contact with a top source/drain of the CFET device 720 on the left side (in FIG. 7B) of the gate 730, and an MD contact 744 over and in electrical contact with a top source/drain 722 of the CFET device 721 on the right side (in FIG. 7B) of the gate 731. The IC device 700B further comprises a bottom source/drain 724 of the CFET device 721 under the top source/drain 722, and a top source/drain 726 which is a common top source/drain of the CFET devices 720, 721. The IC device 700B further comprises conductors 781, 785, BVD vias 771, 775, and a back side power rail 791 configured to supply a power supply voltage, e.g., VSS, to the top semiconductor devices of the CFET devices 720, 721. Various other features of the IC device 700B are not illustrated for simplicity.

The via interconnect 760 is a power wall extending along the X axis and configured for power delivery for the CFET devices 720, 721. The via interconnect 760 is embedded in a gate length defining dielectric structure (not shown) corresponding to a CMG region, and is electrically isolated from the gates 730, 731 by the gate length defining dielectric structure. In some embodiments, the via interconnect 760 corresponds to the via interconnect 460. In some embodiments, the conductors 781, 785 correspond to the conductor 436 and/or are manufactured by the same mask as BMD contacts (not shown) of the IC device 700B. In at least one embodiment, the conductors 781, 785 are thinner than the BMD contacts of the IC device 700B. In some embodiments, the BVD vias 771, 775 correspond to the BVD via 476 and/or are manufactured by the same mask as BVD vias of the IC device 700B.

The MD contact 742 is electrically coupled by the via interconnect 760, the conductor 781 and the BVD via 771 to the power rail 791. The MD contact 744 is electrically coupled by the via interconnect 760, the conductor 785 and the BVD via 775 to the power rail 791. In other words, the via interconnect 760 is configured for power delivery of VSS from the power rail 791 to top semiconductor devices of the CFET devices 720, 721, in a manner similar to that described with respect to the via interconnect 460 in FIG. 4A.

In at least one embodiment, the conductor 781 and the BVD via 771 are omitted, or the conductor 785 and the BVD via 775 are omitted. In some embodiments, the conductors 781, 785 and the BVD vias 771, 775 are all omitted, and the via interconnect 760 is in electrical contact with the power rail 791 in a configuration similar to that described with respect to FIG. 7A and corresponding to the cross-sectional view in FIG. 3A and the layout in FIG. 6A. In some embodiments, the conductors 781, 785 and the BVD vias 771, 775 are replaced with back side vias (not shown) between the power rail 791 and the via interconnect 760 in a configuration corresponding to the cross-sectional view in FIG. 5A and the layout in FIG. 6C. One or more advantages described herein are achievable by the IC device 700B, in accordance with some embodiments.

FIGS. 8A, 8B, 8C, 8D, 8E are schematic cross-sectional views of an IC device 800 at various stages in a manufacturing process, in accordance with some embodiments. In some embodiments, the IC device 800 corresponds to one or more of IC devices 100, 200A, 300A and/or the layouts 200B, 300B. Corresponding components in FIGS. 3A-3B, 8A-8E are designated by the same reference numerals. Upper and lower sides in FIGS. 8A-8E correspond to a front side and a back side of the IC device 800.

In FIG. 8A, a device stack 810 is formed, e.g., as described with respect to FIGS. 1B-1E. The device stack 810 comprises a gate structure 801 and source/drains 322, 332. In some embodiments, the gate structure 801 comprises gates 325, 335 as described with respect to FIG. 3A. A dielectric structure 350 is formed by a CMG mask and corresponds to a CMG region of the CMG mask. In some embodiments, the CMG mask is not a EUV mask. The dielectric structure 350 contacts the gate structure 801 and defines a length of the gate structure 801 along the Y axis. In the example configuration in FIG. 8A, along the Z axis, a top surface 802 of the gate structure 801 is flushed with a top surface 804 of the dielectric structure 350, and a bottom surface 803 of the gate structure 801 is above a bottom surface 805 of the dielectric structure 350. In some embodiments, the dielectric structure 350 is formed by etching, from the front side, an opening into a semiconductor structure comprising the device stack 810, and then filling the opening with a dielectric material. A resulting structure 800A is obtained.

In FIG. 8B, MD contacts are formed over top source/drains in the structure 800A. For example, an MD contact 324 is formed over the source/drain 322 and a portion of the dielectric structure 350. In some embodiments, a mask used for forming MD contacts is a EUV mask. A resulting structure 800B is obtained.

In FIG. 8C, an opening 809 is formed through the dielectric structure 350 to expose a portion of the MD contact 324. The opening 809 is etched from the back side toward the front side and has a shape tapering upwardly as illustrated in FIG. 8C and described with respect to FIG. 3A. In at least one embodiment, the structure 800B is flipped upside down, and the opening 809 is etched from above (i.e., from the back side which is now on top). This upside down orientation is maintained in operations described with respect to FIGS. 8D, 8E. A resulting structure 800C is obtained.

In FIG. 8D, a conductive material is filled in the opening 809 to obtain the via interconnect 360 which is in electrical contact with the MD contact 324. In at least one embodiment, the opening 809 is formed by a separate mask from the CMG mask used for forming the dielectric structure 350, and the via interconnect 360 is a power via, e.g., as described with respect to FIG. 7A. In at least one embodiment, the opening 809 is formed by the CMG mask used for forming the dielectric structure 350, and the via interconnect 360 is a power wall, e.g., as described with respect to FIG. 7B. A resulting structure 800D is obtained.

In FIG. 8E, a BMD contact 334 is formed over the source/drain 332. In some embodiments, a mask used for forming BMD contacts is a EUV mask. Next, a BVD via 374 is formed over the BMD contact 334. Subsequently, a BM0 layer is deposited over the BVD via 374, and patterned to form a power rail 391 in electrical contact with the bottom surface 362 of the via interconnect 360, and a further power rail 393 in electrical contact with the BVD via 374. As a result, a structure 800E corresponding to the IC device 300A described with respect to FIG. 3A is obtained. In at least one embodiment, one or more advantages described herein are achievable by the IC device 800 manufactured as described with respect to FIGS. 8A-8E.

FIGS. 9A, 9B, 9C, 9D, 9E are schematic cross-sectional views of an IC device 900 at various stages in a manufacturing process, in accordance with some embodiments. In some embodiments, the IC device 900 corresponds to one or more of IC devices 100, 200A, 400A and/or the layouts 200B, 400B. Corresponding components in FIGS. 3A-3B, 4A-4B, 8A-8E, 9A-9E are designated by the same reference numerals. Upper and lower sides in FIGS. 9A-9E correspond to a front side and a back side of the IC device 900.

In FIG. 9A, the device stack 810 is formed, e.g., as described with respect to FIGS. 1B-1E. A dielectric structure 450 is formed by a CMG mask and corresponds to a CMG region of the CMG mask. The dielectric structure 450 contacts the gate structure 801 and defines a length of the gate structure 801 along the Y axis. In the example configuration in FIG. 9A, along the Z axis, the top surface 802 of the gate structure 801 is flushed with a top surface 904 of the dielectric structure 450, and the bottom surface 803 of the gate structure 801 is flush with a bottom surface 905 of the dielectric structure 450. In some embodiments, the dielectric structure 450 is formed by etching, from the front side, an opening into a semiconductor structure comprising the device stack 810, and then filling the opening with a dielectric material. A resulting structure 900A is obtained.

In FIG. 9B, an opening 909 is formed through the dielectric structure 450. The opening 909 is etched from the front side toward the back side and has a shape tapering downwardly as illustrated in FIG. 9B and described with respect to FIG. 4A. A resulting structure 900B is obtained.

In FIG. 9C, a conductive material is filled in the opening 909 to obtain the via interconnect 460. In at least one embodiment, the opening 909 is formed by a separate mask from the CMG mask used for forming the dielectric structure 450, and the via interconnect 460 is a power via, e.g., as described with respect to FIG. 7A. In at least one embodiment, the opening 909 is formed by the CMG mask used for forming the dielectric structure 450, and the via interconnect 460 is a power wall, e.g., as described with respect to FIG. 7B. A resulting structure 900C is obtained.

In FIG. 9D, MD contacts are formed over top source/drains in the structure 900C. For example, an MD contact 324 is formed over the source/drain 322 and a portion of each of the dielectric structure 450 and the via interconnect 460, so that the MD contact 324 is in electrical contact with the via interconnect 460. The resulting structure is then flipped upside down, and this upside down orientation is maintained in remaining operations described with respect to FIGS. 9D, 9E. A BMD contact 334 is formed over the source/drain 332 and, simultaneously and using the same mask, a conductor 436 is formed over and in electrical contact with the bottom surface 462 of the via interconnect 460. In some embodiments, the mask used for forming BMD contacts and conductors, such as the conductor 436, is a EUV mask. A resulting structure 900D is obtained.

In FIG. 9E, a BVD via 374 is formed over the BMD contact 334 and, simultaneously and using the same mask, a BVD via 476 is formed over and in electrical contact with the conductor 436. Subsequently, a BM0 layer is deposited over the BVD vias 374, 476, and patterned to form a power rail 391 in electrical contact with the BVD via 476, and a further power rail 393 in electrical contact with the BVD via 374. As a result, a structure 900E corresponding to the IC device 400A described with respect to FIG. 4A is obtained. In at least one embodiment, one or more advantages described herein are achievable by the IC device 900 manufactured as described with respect to FIGS. 9A-9E.

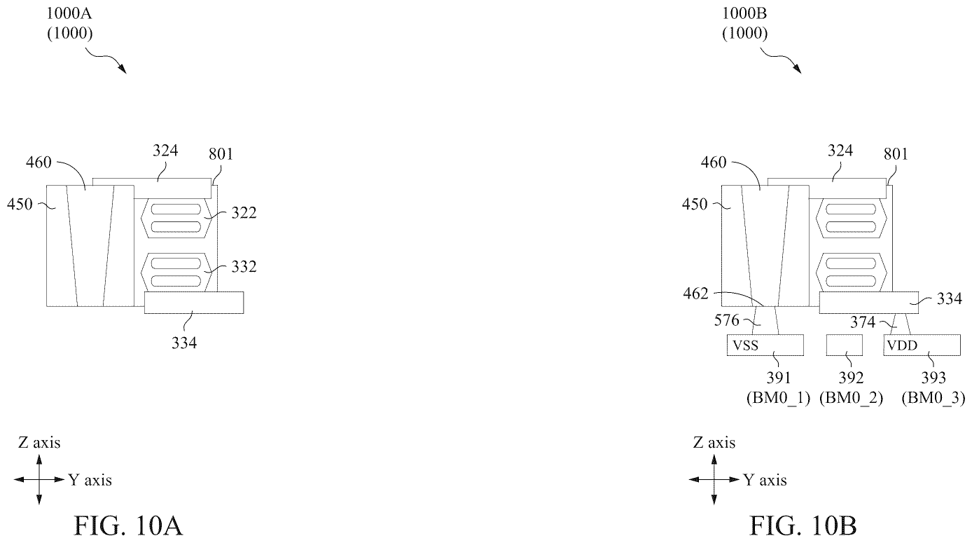

FIGS. 10A, 10B are schematic cross-sectional views of an IC device 1000 at various stages in a manufacturing process, in accordance with some embodiments. In some embodiments, the IC device 1000 corresponds to one or more of IC devices 100, 200A, 500A and/or the layouts 200B, 500B. Corresponding components in FIGS. 3A-3B, 4A-4B, 5A-5B, 8A-8E, 9A-9E, 10A-10B are designated by the same reference numerals. Upper and lower sides in FIGS. 10A, 10B correspond to a front side and a back side of the IC device 1000. Operations described in detail with respect to FIGS. 10A, 10B are performed in the upside down orientation as described herein.

In FIG. 10A, a structure similar to the structure 900D is obtained by operations described with respect to FIGS. 9A-9D, with the exception that the conductor 436 is not formed over the via interconnect 460. A resulting structure 1000A is obtained.

In FIG. 10B, a BVD via 374 is formed over the BMD contact 334, and a back side via 576 is formed over and in electrical contact with the bottom surface 462 of the via interconnect 460. The BVD via 374 and other BVD vias are formed by a mask different from a mask used for forming the back side via 576. In some embodiments, a mask used for forming back side vias, such as the back side via 576, is a EUV mask. In some embodiments, the BVD vias are formed before the back side via 576. In at least one embodiment, the back side via 576 is formed before the BVD vias. Subsequently, a BM0 layer is deposited over the BVD via 374 and back side via 576, and patterned to form a power rail 391 in electrical contact with the back side via 576, and a further power rail 393 in electrical contact with the BVD via 374. As a result, a structure 1000B corresponding to the IC device 500A described with respect to FIG. 5A is obtained. In at least one embodiment, one or more advantages described herein are achievable by the IC device 1000 manufactured as described with respect to FIGS. 10A, 10B.

FIG. 11A includes a schematic diagram of a portion of an IC manufacturing process 1100A, and schematic views of an IC device at various stages in the manufacturing process, in accordance with some embodiments. In some embodiments, the process 1100A is performed to manufacture one or more of the IC devices 100, 200A, 300A, 400A, 500A, 700A, 700B, 800, 900, 1000 and/or in accordance with one or more of the layouts 200B, 300B, 400B, 500B, 600A, 600B, 600C. The process 1100A comprises operations 1102, 1104, 1106, 1108.

At operation 1102, a semiconductor structure 1120 is formed. In at least one embodiment, one or more operations described with respect to FIGS. 1B-1F are performed to obtain the semiconductor structure 1120. The semiconductor structure 1120 comprises a plurality of elongated, continuous gate structures 1130, 1140, 1150, 1160, 1170 extending across first and second active regions 1121, 1122. Each of the active regions 1121, 1122 comprises a bottom active region and a top active region stacked over the bottom active region, as described herein. Each of the gate structures 1130, 1140, 1150, 1160, 1170 comprises a first all-around gate extending around one or more channels in the top active region, and a second all-around gate extending around one or more channels in the bottom active region, as described herein.

At operation 1104, CMG openings 1181, 1182, 1183 are formed, e.g., by etching, in the semiconductor structure 1120 using a CMG mask. In some embodiments, such a CMG mask is not a EUV mask. This operation is sometimes referred to as CMG patterning. Each of the CMG openings 1181, 1182, 1183 corresponds to a CMG region, as described herein. Each of the CMG openings 1181, 1182, 1183 extends through an entire thickness, or height, of the gate structures 1130, 1140, 1150, 1160, 1170, to cut or severe each of the gate structures 1130, 1140, 1150, 1160, 1170 into disconnected sections. For example, the gate structures 1130, 1140, 1150, 1160, 1170 are cut into corresponding gate structures 1131 and 1132, 1141 and 1142, 1151 and 1152, 1161 and 1162, 1171 and 1172. For simplicity, in the subsequent operations, the gate structures 1132, 1142, 1152, 1162, 1172, the active region 1122, and structures corresponding to the CMG opening 1183 are not illustrated.

At operation 1106, a conformal deposition of a dielectric material is performed, to deposit the dielectric material over side walls of a CMG opening where a via interconnect is to be later formed. In an example process, a conformal deposition process, such as ALD, is performed to deposit a conformal layer 1185 of the dielectric material over side walls of the CMG opening 1182, followed by an anisotropic etching to remove portions of the conformal layer other than the portions on the side walls of the CMG opening 1182. As a result, a middle region 1186 of the CMG opening 1182 remains unfilled. Other CMG openings where a via interconnect is not to be formed later are filled with a dielectric material to form corresponding dielectric structures. For example, the CMG opening 1181 is filled with a dielectric material to obtain a dielectric structure 1184.

At operation 1108, a conductive material is deposited in the unfilled middle region 1186 of the CMG opening 1182, to obtain a via interconnect 1187. In some embodiments, the via interconnect 1187 corresponds to one or more of the via interconnects described herein, and the layer 1185 of the dielectric material corresponds to one or more of the dielectric structures surrounding such via interconnects, as described herein. In at least one embodiment, the via interconnect 1187 corresponds to a power wall as described herein. In some embodiments, the described formation of the via interconnect 1187 is applicable to fabricate one or more of the via interconnects 360, 460 in one or more the processes described with respect to FIGS. 8A-8E, 9A-9E, 10A-10B.

In the described example process 1100A, an extra mask is not required for the formation of the via interconnect 1187. Specifically, the via interconnect 1187 is self-aligned, and formed by the CMG mask. In at least one embodiment, this is an advantage, because the manufacturing process is not significantly complicated by the formation of via interconnects. In at least one embodiment, one or more advantages described herein are achievable by one or more IC devices manufactured in accordance with the process 1100A.

FIG. 11B includes a schematic diagram of a portion of an IC manufacturing process 1100B, and schematic views of an IC device at various stages in the manufacturing process, in accordance with some embodiments. In some embodiments, the process 1100B is performed to manufacture one or more of the IC devices 100, 200A, 300A, 400A, 500A, 700A, 700B, 800, 900, 1000 and/or in accordance with one or more of the layouts 200B, 300B, 400B, 500B, 600A, 600B, 600C. Components in FIG. 11B having corresponding components in FIG. 11A are designated by the same reference numerals as in FIG. 11A.

The process 1100B comprises operations 1102 and 1104 as described with respect to FIG. 11A, and operations 1110, 1112, 1114. For simplicity, operation 1102 and various features of operation 1104 are not illustrated in FIG. 11B, and the description of operation 1104 is not repeated.

At operation 1110, a dielectric material is deposited in all CMG openings to form corresponding dielectric structures. For example, the CMG openings 1181, 1182 are filled with a dielectric material to obtain corresponding dielectric structures 1184, 1195.

At operation 1112, a via patterning process is performed to form a via opening in a dielectric structure where a via interconnect is to be formed later. For example, an etching process is performed using an additional mask to form a via opening 1196 in the dielectric structure 1195. In some embodiments, the additional mask used for forming the via opening 1196, or the like, is a EUV mask.

At operation 1114, a conductive material is deposited in the via opening 1196, to obtain a via interconnect 1197. In some embodiments, the via interconnect 1197 corresponds to one or more of the via interconnects described herein, and the dielectric structure 1195 corresponds to one or more of the dielectric structures surrounding such via interconnects, as described herein. In at least one embodiment, the via interconnect 1197 corresponds to a power via as described herein. In some embodiments, the described formation of the via interconnect 1197 is applicable to fabricate one or more of the via interconnects 360, 460 in one or more the processes described with respect to FIGS. 8A-8E, 9A-9E, 10A-10B. In at least one embodiment, one or more advantages described herein are achievable by one or more IC devices manufactured in accordance with the process 1100B.

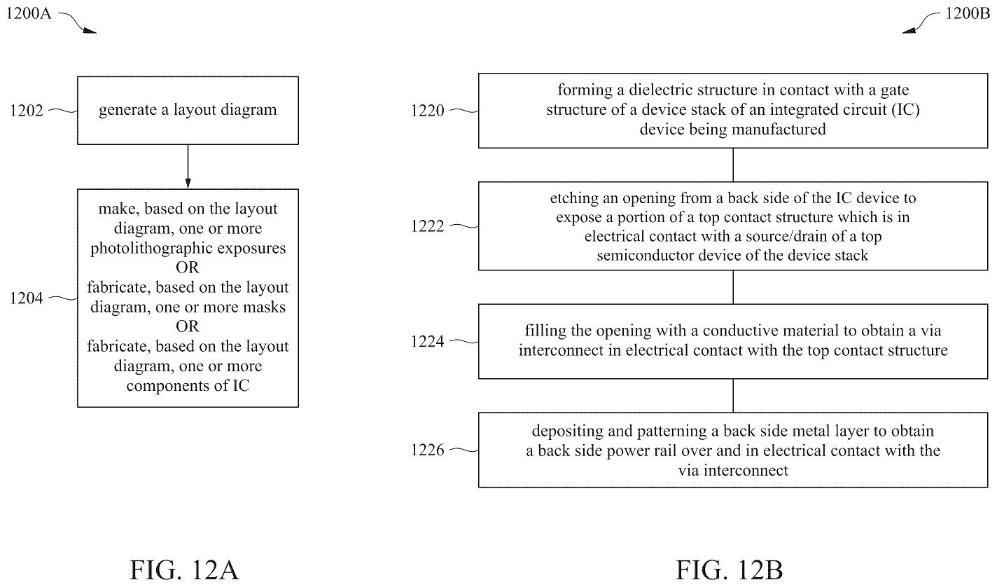

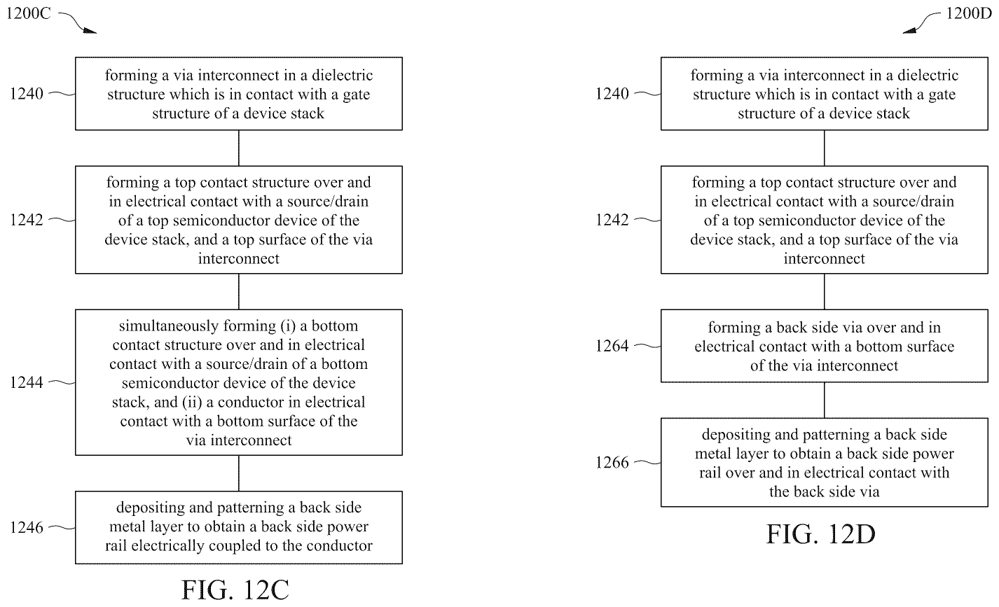

FIG. 12A is a flowchart of a method 1200A of generating a layout and using the layout to manufacture an IC device, in accordance with some embodiments. Method 1200A is implementable, for example, using an EDA system and/or an integrated circuit (IC) manufacturing system as described herein, in accordance with some embodiments. Regarding method 1200A, examples of the layout include the layouts disclosed herein, or the like. Examples of an IC device to be manufactured according to method 1200A include one or more of the IC devices disclosed herein.

At operation 1202, a layout is generated which, among other things, includes at least one via interconnect embedded in a dielectric structure corresponding to a cut-gate region of a cut-gate mask, as described herein. The via interconnect is configured to deliver power to a top semiconductor device from a back side power rail, as described herein.

At operation 1204, based on the layout, at least one of (A) one or more photolithographic exposures are made or (B) one or more semiconductor masks are fabricated or (C) one or more components in a layer of an IC device are fabricated. Examples of operation 1204 are described with respect to FIGS. 12B-12D.

FIG. 12B is a flowchart of a method 1200B of manufacturing an IC device, in accordance with some embodiments. The flowchart of FIG. 12B shows additional operations that demonstrate one or more examples of procedures implementable in operation 1204 of FIG. 12A, in accordance with one or more embodiments. The method 1200B comprises operations 1220, 1222, 1224, 1226.

At operation 1220, a dielectric structure is formed to be in contact with a gate structure of a device stack of an integrated circuit (IC) device being manufactured. For example, as described with respect to FIG. 8A, a dielectric structure 350 is formed to be in contact with a gate structure 801 of a device stack 810 of an IC device being manufactured.

At operation 1222, an opening is etched from a back side of the IC device to expose a portion of a top contact structure which is in electrical contact with a source/drain of a top semiconductor device of the device stack. For example, as described with respect to FIG. 8C, an opening 809 is etched from the back side of the IC device to expose a portion of a top contact structure 324 which is in electrical contact with a source/drain 322 of a top semiconductor device of the device stack 810.

At operation 1224, the opening is filled with a conductive material to obtain a via interconnect in electrical contact with the top contact structure. For example, as described with respect to FIG. 8D, the opening is filled with a conductive material to obtain a via interconnect 360 in electrical contact with the top contact structure 324.

At operation 1226, a back side metal layer is deposited and patterned to obtain a back side power rail over and in electrical contact with the via interconnect. For example, as described with respect to FIG. 8E, a BM0 layer is deposited and patterned to obtain a back side power rail 391 over and in electrical contact with the via interconnect 360. In at least one embodiment, one or more advantages described herein are achievable by an IC device manufactured in accordance with the method 1200B.

FIG. 12C is a flowchart of a method 1200C of manufacturing an IC device, in accordance with some embodiments. The flowchart of FIG. 12C shows additional operations that demonstrate one or more examples of procedures implementable in operation 1204 of FIG. 12A, in accordance with one or more embodiments. The method 1200C comprises operations 1240, 1242, 1244, 1246.

At operation 1240, a via interconnect is formed in a dielectric structure which is in contact with a gate structure of a device stack. For example, as described with respect to FIGS. 9A-9C, a via interconnect 460 is formed in a dielectric structure 450 which is in contact with a gate structure 801 of a device stack 810.

At operation 1242, a top contact structure is formed over and in electrical contact with a source/drain of a top semiconductor device of the device stack, and a top surface of the via interconnect. For example, as described with respect to FIG. 9D, a top contact structure 342 is formed over and in electrical contact with a source/drain 322 of a top semiconductor device of the device stack 801, and a top surface of the via interconnect 460.

At operation 1244, a bottom contact structure and a conductor are simultaneously formed. The bottom contact structure is formed over and in electrical contact with a source/drain of a bottom semiconductor device of the device stack. The conductor is formed in electrical contact with a bottom surface of the via interconnect. For example, as described with respect to FIG. 9E, a bottom contact structure 334 and a conductor 436 are simultaneously formed, e.g., by using the same mask for forming BMD contacts. The bottom contact structure 334 is formed over and in electrical contact with a source/drain 332 of a bottom semiconductor device of the device stack 810. The conductor 436 is formed in electrical contact with a bottom surface 462 of the via interconnect 460.

At operation 1246, a back side metal layer is deposited and patterned to obtain a back side power rail electrically coupled to the conductor. For example, as described with respect to FIG. 9E, a BM0 layer is deposited and patterned to obtain a back side power rail 391 which is electrically coupled to the conductor 436 through a BVD via 476. In at least one embodiment, one or more advantages described herein are achievable by an IC device manufactured in accordance with the method 1200C.

FIG. 12D is a flowchart of a method 1200D of manufacturing an IC device, in accordance with some embodiments. The flowchart of FIG. 12D shows additional operations that demonstrate one or more examples of procedures implementable in operation 1204 of FIG. 12A, in accordance with one or more embodiments. The method 1200D comprises operations 1240, 1242, 1264, 1266.

Operations 1240, 1242 are as described with respect to FIG. 12C.

At operation 1264, a back side via is formed over and in electrical contact with a bottom surface of the via interconnect. For example, as described with respect to FIG. 10A, a back side via 576 is formed over and in electrical contact with a bottom surface 462 of the via interconnect 460.

At operation 1266, a back side metal layer is deposited and patterned to obtain a back side power rail over and in electrical contact with the back side via. For example, as described with respect to FIG. 10B, a BM0 layer is deposited and patterned to obtain a back side power rail 391 over and in electrical contact with the back side via 576. In at least one embodiment, one or more advantages described herein are achievable by an IC device manufactured in accordance with the method 1200D.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, at least one method(s) discussed above is performed in whole or in part by at least one EDA system. In some embodiments, an EDA system is usable as part of a design house of an IC manufacturing system discussed below.

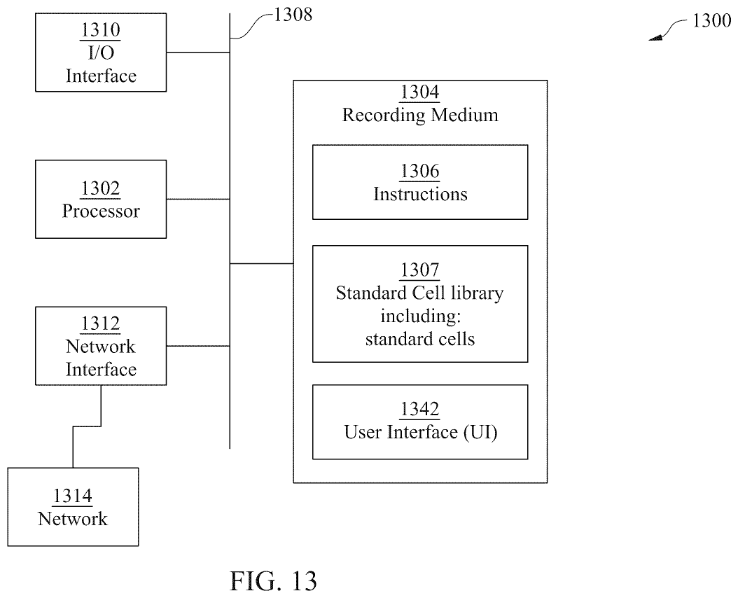

FIG. 13 is a block diagram of an electronic design automation (EDA) system 1300 in accordance with some embodiments.

In some embodiments, EDA system 1300 includes an APR system. Methods described herein of designing layouts represent wire routing arrangements, in accordance with one or more embodiments, are implementable, for example, using EDA system 1300, in accordance with some embodiments.

In some embodiments, EDA system 1300 is a general purpose computing device including a hardware processor 1302 and a non-transitory, computer-readable recording medium 1304. Recording medium 1304, amongst other things, is encoded with, i.e., stores, computer program code 1306, i.e., a set of executable instructions. Execution of instructions 1306 by hardware processor 1302 represents (at least in part) an EDA tool which implements a portion or all of the methods described herein in accordance with one or more embodiments (hereinafter, the noted processes and/or methods).

Processor 1302 is electrically coupled to computer-readable recording medium 1304 via a bus 1308. Processor 1302 is also electrically coupled to an I/O interface 1310 by bus 1308. A network interface 1312 is also electrically connected to processor 1302 via bus 1308. Network interface 1312 is connected to a network 1314, so that processor 1302 and computer-readable recording medium 1304 are capable of connecting to external elements via network 1314. Processor 1302 is configured to execute computer program code 1306 encoded in computer-readable recording medium 1304 in order to cause system 1300 to be usable for performing a portion or all of the noted processes and/or methods. In one or more embodiments, processor 1302 is a central processing unit (CPU), a multi-processor, a distributed processing system, an application specific integrated circuit (ASIC), and/or a suitable processing unit.

In one or more embodiments, computer-readable recording medium 1304 is an electronic, magnetic, optical, electromagnetic, infrared, and/or a semiconductor system (or apparatus or device). For example, computer-readable recording medium 1304 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable recording medium 1304 includes a compact disk-read only memory (CD-ROM), a compact disk-read/write (CD-R/W), and/or a digital video disc (DVD).

In one or more embodiments, recording medium 1304 stores computer program code 1306 configured to cause system 1300 (where such execution represents (at least in part) the EDA tool) to be usable for performing a portion or all of the noted processes and/or methods. In one or more embodiments, recording medium 1304 also stores information which facilitates performing a portion or all of the noted processes and/or methods. In one or more embodiments, recording medium 1304 stores library 1307 of standard cells including such standard cells as disclosed herein.

EDA system 1300 includes I/O interface 1310. I/O interface 1310 is coupled to external circuitry. In one or more embodiments, I/O interface 1310 includes a keyboard, keypad, mouse, trackball, trackpad, touchscreen, and/or cursor direction keys for communicating information and commands to processor 1302.

EDA system 1300 also includes network interface 1312 coupled to processor 1302. Network interface 1312 allows system 1300 to communicate with network 1314, to which one or more other computer systems are connected. Network interface 1312 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1300.

System 1300 is configured to receive information through I/O interface 1310. The information received through I/O interface 1310 includes one or more of instructions, data, design rules, libraries of standard cells, and/or other parameters for processing by processor 1302. The information is transferred to processor 1302 via bus 1308. EDA system 1300 is configured to receive information related to a UI through I/O interface 1310. The information is stored in computer-readable recording medium 1304 as user interface (UI) 1342.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1300. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

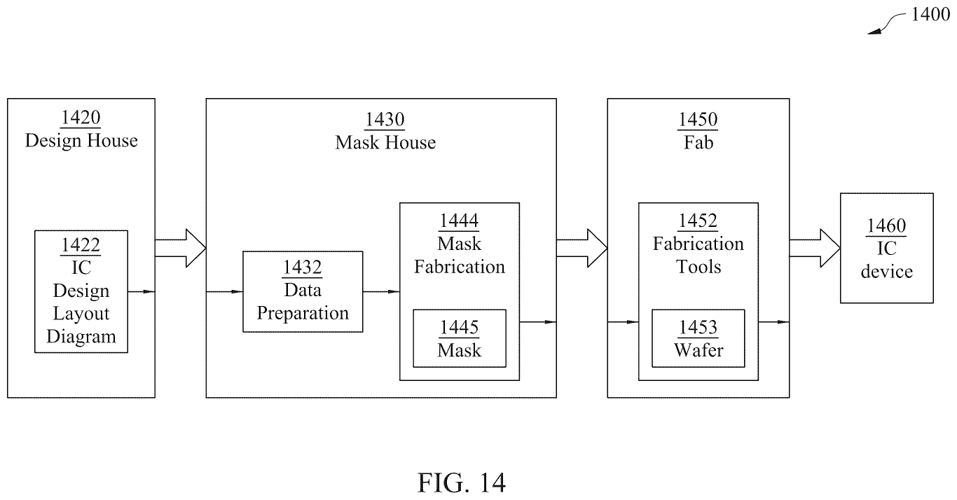

FIG. 14 is a block diagram of an integrated circuit (IC) manufacturing system 1400, and an IC manufacturing flow associated therewith, in accordance with some embodiments. In some embodiments, based on a layout, at least one of (A) one or more semiconductor masks or (B) at least one component in a layer of a semiconductor integrated circuit is fabricated using manufacturing system 1400.

In FIG. 14, IC manufacturing system 1400 includes entities, such as a design house 1420, a mask house 1430, and an IC manufacturer/fabricator (“fab”) 1450, that interact with one another in the design, development, and manufacturing cycles and/or services related to manufacturing an IC device 1460. The entities in system 1400 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1420, mask house 1430, and IC fab 1450 is owned by a single larger company. In some embodiments, two or more of design house 1420, mask house 1430, and IC fab 1450 coexist in a common facility and use common resources.

Design house (or design team) 1420 generates an IC design layout 1422. IC design layout 1422 includes various geometrical patterns designed for an IC device 1460. The geometrical patterns correspond to patterns of metal, oxide, or semiconductor layers that make up the various components of IC device 1460 to be fabricated. The various layers combine to form various IC features. For example, a portion of IC design layout 1422 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1420 implements a proper design procedure to form IC design layout 1422. The design procedure includes one or more of logic design, physical design or place-and-route operation. IC design layout 1422 is presented in one or more data files having information of the geometrical patterns. For example, IC design layout 1422 can be expressed in a GDSII file format or DFII file format.

Mask house 1430 includes data preparation 1432 and mask fabrication 1444. Mask house 1430 uses IC design layout 1422 to manufacture one or more masks 1445 to be used for fabricating the various layers of IC device 1460 according to IC design layout 1422. Mask house 1430 performs mask data preparation 1432, where IC design layout 1422 is translated into a representative data file (“RDF”). Mask data preparation 1432 provides the RDF to mask fabrication 1444. Mask fabrication 1444 includes a mask writer. A mask writer converts the RDF to an image on a substrate, such as a mask (reticle) 1445 or a semiconductor wafer 1453. The design layout 1422 is manipulated by mask data preparation 1432 to comply with particular characteristics of the mask writer and/or requirements of IC fab 1450. In FIG. 14, mask data preparation 1432 and mask fabrication 1444 are illustrated as separate elements. In some embodiments, mask data preparation 1432 and mask fabrication 1444 can be collectively referred to as mask data preparation.

In some embodiments, mask data preparation 1432 includes optical proximity correction (OPC) which uses lithography enhancement techniques to compensate for image errors, such as those that can arise from diffraction, interference, other process effects and the like. OPC adjusts IC design layout 1422. In some embodiments, mask data preparation 1432 includes further resolution enhancement techniques (RET), such as off axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1432 includes a mask rule checker (MRC) that checks the IC design layout 1422 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout 1422 to compensate for limitations during mask fabrication 1444, which may undo part of the modifications performed by OPC in order to meet mask creation rules.

In some embodiments, mask data preparation 1432 includes lithography process checking (LPC) that simulates processing that will be implemented by IC fab 1450 to fabricate IC device 1460. LPC simulates this processing based on IC design layout 1422 to create a simulated manufactured device, such as IC device 1460. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 1422.

It should be understood that the above description of mask data preparation 1432 has been simplified for the purposes of clarity. In some embodiments, data preparation 1432 includes additional features such as a logic operation (LOP) to modify the IC design layout 1422 according to manufacturing rules. Additionally, the processes applied to IC design layout 1422 during data preparation 1432 may be executed in a variety of different orders.

After mask data preparation 1432 and during mask fabrication 1444, a mask 1445 or a group of masks 1445 are fabricated based on the modified IC design layout 1422. In some embodiments, mask fabrication 1444 includes performing one or more lithographic exposures based on IC design layout 1422. In some embodiments, an electron-beam (e-beam) or a mechanism of multiple e-beams is used to form a pattern on a mask (photomask or reticle) 1445 based on the modified IC design layout 1422. Mask 1445 can be formed in various technologies. In some embodiments, mask 1445 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1445 includes a transparent substrate (e.g., fused quartz) and an opaque material (e.g., chromium) coated in the opaque regions of the binary mask. In another example, mask 1445 is formed using a phase shift technology. In a phase shift mask (PSM) version of mask 1445, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1444 is used in a variety of processes. For example, such a mask(s) is used in an ion implantation process to form various doped regions in semiconductor wafer 1453, in an etching process to form various etching regions in semiconductor wafer 1453, and/or in other suitable processes.

IC fab 1450 is an IC fabrication business that includes one or more manufacturing facilities for the fabrication of a variety of different IC products. In some embodiments, IC Fab 1450 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1450 includes fabrication tools 1452 configured to execute various manufacturing operations on semiconductor wafer 1453 such that IC device 1460 is fabricated in accordance with the mask(s), e.g., mask 1445. In various embodiments, fabrication tools 1452 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1450 uses mask(s) 1445 fabricated by mask house 1430 to fabricate IC device 1460. Thus, IC fab 1450 at least indirectly uses IC design layout 1422 to fabricate IC device 1460. In some embodiments, semiconductor wafer 1453 is fabricated by IC fab 1450 using mask(s) 1445 to form IC device 1460. In some embodiments, the IC fabrication includes performing one or more lithographic exposures based at least indirectly on IC design layout 1422. Semiconductor wafer 1453 includes a silicon substrate or other proper substrate having material layers formed thereon. Semiconductor wafer 1453 further includes one or more of various doped regions, dielectric features, multilevel interconnects, and the like (formed at subsequent manufacturing steps).

In some embodiments, an integrated circuit (IC) device comprises a device stack, a top contact structure, a back side power rail, and a via interconnect. The device stack comprises a bottom semiconductor device, and a top semiconductor device stacked over the bottom semiconductor device along a direction. The top contact structure is over and in electrical contact with a source/drain of the top semiconductor device. The via interconnect extends between and electrically couples the top contact structure and the back side power rail. The via interconnect tapers along the direction from the back side power rail towards the top contact structure.

In some embodiments, an integrated circuit (IC) device comprises a device stack, top contact structure, a bottom contact structure, a conductor, a via interconnect and a back side power rail. The device stack comprises a bottom semiconductor device, and a top semiconductor device stacked over the bottom semiconductor device along a direction. The top contact structure is over and in electrical contact with a source/drain of the top semiconductor device. The bottom contact structure is under and in electrical contact with a source/drain of the bottom semiconductor device. The conductor is co-elevational with, spaced from, and thinner than, the bottom contact structure. The via interconnect extends between and electrically couples the top contact structure and the conductor. The back side power rail is under and electrically coupled to the conductor.

In some embodiments, a method comprises forming a via interconnect in a dielectric structure which is in contact with a gate structure of a device stack. The method further comprises forming a top contact structure over and in electrical contact with a source/drain of a top semiconductor device of the device stack, and a top surface of the via interconnect. The method further comprises forming a back side via over and in electrical contact with a bottom surface of the via interconnect. The method further comprises depositing and patterning a back side metal layer to obtain a back side power rail over and in electrical contact with the back side via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is

1. An integrated circuit (IC) device, comprising:
a device stack comprising:
a bottom semiconductor device, and
a top semiconductor device stacked over the bottom semiconductor device along a direction;
a top contact structure over and in electrical contact with a source/drain of the top semiconductor device;
a back side power rail; and
a via interconnect extending between and electrically coupling the top contact structure and the back side power rail,
wherein the via interconnect tapers along the direction from the back side power rail towards the top contact structure.

2. The IC device of claim 1, wherein the via interconnect is in direct contact with the back side power rail.

3. The IC device of claim 1, wherein
in a view along the direction, the top contact structure overlaps less than a half of the via interconnect.

4. The IC device of claim 1, further comprising:
a dielectric structure co-elevational with, and in contact with, gates of the top semiconductor device and the bottom semiconductor device,
wherein the via interconnect is embedded in the dielectric structure.

5. The IC device of claim 1, wherein
along the direction, the via interconnect has a top surface between a top surface and a bottom surface of the top contact structure.

6. The IC device of claim 1, wherein
a center line of the back side power rail is aligned with a center line of the via interconnect.

7. The IC device of claim 1, wherein
the back side power rail and the via interconnect are elongated along a first direction, and
the top contact structure is elongated along a second direction transverse to the first direction.

8. The IC device of claim 1, further comprising:
a further top contact structure over and in electrical contact with a further source/drain of the top semiconductor device,
wherein
the back side power rail and the via interconnect are elongated along a first direction,
the top contact structure and the further top contact structure are elongated along a second direction transverse to the first direction, and
along the second direction, the further top contact structure overlaps the via interconnect.

9. The IC device of claim 1, further comprising:
a further device stack comprising:
a further bottom semiconductor device, and
a further top semiconductor device stacked over the further bottom semiconductor device along the direction; and
a further top contact structure over and in electrical contact with a source/drain of the further top semiconductor device,
wherein the via interconnect extends between and electrically coupling the further top contact structure and the back side power rail.

10. The IC device of claim 1, further comprising:
a plurality of metal layers over the device stack,
wherein, among the plurality of metal layers, a metal layer closest to the device stack is free of a power rail directly over the device stack.

11. An integrated circuit (IC) device, comprising:
a device stack comprising:
a bottom semiconductor device, and
a top semiconductor device stacked over the bottom semiconductor device along a direction;
a top contact structure over and in electrical contact with a source/drain of the top semiconductor device;
a bottom contact structure under and in electrical contact with a source/drain of the bottom semiconductor device;
a conductor co-elevational with, spaced from, and thinner than, the bottom contact structure;
a via interconnect extending between and electrically coupling the top contact structure and the conductor; and
a back side power rail under and electrically coupled to the conductor.

12. The IC device of claim 11, wherein
in a view along the direction, the top contact structure overlaps less than a half of the via interconnect.

13. The IC device of claim 11, wherein
a center line of the back side power rail is aligned with at least one of
a center line of the via interconnect, or
a centerline of the conductor.

14. The IC device of claim 11, wherein
in a view along the direction, the back side power rail overlaps an entirety of the conductor.

15. The IC device of claim 11, further comprising:
a further top contact structure over and in electrical contact with a further source/drain of the top semiconductor device,
wherein
the back side power rail and the via interconnect are elongated along a first direction,
the top contact structure and the further top contact structure are elongated along a second direction transverse to the first direction, and
along the second direction, the further top contact structure overlaps the via interconnect.

16. The IC device of claim 11, further comprising:
a further device stack comprising:
a further bottom semiconductor device, and
a further top semiconductor device stacked over the further bottom semiconductor device along the direction;
a further top contact structure over and in electrical contact with a source/drain of the further top semiconductor device; and
a further conductor co-elevational with, spaced from, and thinner than, the bottom contact structure,
wherein
the via interconnect extends between and electrically coupling the further top contact structure and the further conductor, and
the back side power rail is under and electrically coupled to the further conductor.

17. The IC device of claim 11, further comprising:
a plurality of metal layers over the device stack,
wherein, among the plurality of metal layers, a metal layer closest to the device stack is free of a power rail directly over the device stack.

18. A method, comprising:
forming a via interconnect in a dielectric structure which is in contact with a gate structure of a device stack;
forming a top contact structure over and in electrical contact with
a source/drain of a top semiconductor device of the device stack, and
a top surface of the via interconnect;
forming a back side via over and in electrical contact with a bottom surface of the via interconnect; and
depositing and patterning a back side metal layer to obtain a back side power rail over and in electrical contact with the back side via.

19. The method of claim 18, wherein the forming the via interconnect comprises:
etching an opening into a semiconductor structure, wherein
the semiconductor structure comprises a plurality of gate structures including the gate structure of the device stack, the plurality of gate structures arranged side by side along a first axis and elongated along a second axis transverse to the first axis, and
the opening is elongated along the first axis and cuts through the plurality of gate structures;
depositing a dielectric material in the opening to obtain the dielectric structure;
etching a via opening in the dielectric structure; and
filling the via opening with a conductive material to obtain the via interconnect.

20. The method of claim 18, wherein the forming the via interconnect comprises:
etching an opening into a semiconductor structure, wherein
the semiconductor structure comprises a plurality of gate structures including the gate structure of the device stack, the plurality of gate structures arranged side by side along a first axis and elongated along a second axis transverse to the first axis, and
the opening is elongated along the first axis and cuts through the plurality of gate structures;
depositing a conformal layer of a dielectric material over side walls of the opening, while leaving a middle region of the opening unfilled; and
filing the middle region of the opening with a conductive material to obtain the via interconnect which is elongated along the first axis and is electrically isolated from cut ends of the plurality of gate structures by the dielectric material over the side walls of the opening.
